(19) United States
(12) Patent Application Publication
(10) Pub. No.: US 2024/0397658 A1
(43) Pub. Date: Nov. 28, 2024

(54) COMPUTER DATA CENTER RACK ASSEMBLY

(71) Applicant: MacStadium, Inc., Atlanta, GA (US)

(72) Inventors: Corey Layton, Cartersville, GA (US); Mark Benati, Northglenn, CO (US); Paul Benati, Roswell, GA (US); Emil Santiago, Henderson, NV (US)

(21) Appl. No.: 18/673,048

(22) Filed: May 23, 2024

Related U.S. Application Data
(60) Provisional application No. 63/503,840, filed on May 23, 2023.

(51) Int. Cl. H05K 7/14; H05K 7/20

(52) U.S. Cl. CPC H05K 7/1489; H05K 7/2039; H05K 7/20709

(57) ABSTRACT

A mounting assembly is disclosed and can comprise a stand configured to hold a computer in an upright orientation and a base comprising a plurality of edge walls define an internal void configured to hold the computer, a first motor attachment point, and a first secondary computing device (SCD) attachment point. The mounting assembly can include a motor mount configured to receive a motor actuator, and the motor mount can have a second motor attachment point configured to detachably attach to the first motor attachment point. The mounting assembly can include a SCD mount configured to attach to a secondary computing device, and the SCD mount can have a SCD attachment point configured to detachably attach to the first SCD attachment points.

### CROSS REFERENCE TO RELATED APPLICATIONS

This application claims the benefit of, and priority to, U.S. Provisional Patent Application No. 63/503,840, filed May 23, 2023, and entitled “Computer Data Center Rack Assembly,” the disclosure of which is incorporated by reference in its entirety as if the same was fully set forth herein.

### TECHNICAL FIELD

The present disclosure relates generally to the field of storing and organizing computer systems and, in particular, large scale computer systems.

### BACKGROUND

Computer data centers are facilities that contain racks or shelves of computer systems and their associated components such as power supplies and telecommunications systems. Large data centers house hundreds, often thousands, of separate computers, which are connected for communications with computers in the data center and with telecommunication networks such as the Internet, thereby forming the essential infrastructure of “cloud computing.” The racks of computers often extend from floor to ceiling, mounted atop hollow flooring structures called plenums that route cooling air to the various racks, with heat removal vents positioned above the racks. A facility housing thousands of computers uses many kilowatts of electricity and generates large amounts of heat that must be removed so that the computers can operate within their specified ranges of operating temperatures.

Space, cooling, power cabling, and communications cabling requirements are therefore critical for modern data centers. Floor space in terms of square feet footprint per rack and height requirements for each rack of computers are limited, so as to provide required cooling air and power requirements, as well as security within physical cages and accessibility for configuration and maintenance.

Two particular types of computers that are popular for certain computing applications are the APPLE® Mac mini (marketed as “Mac mini”) and the APPLE® Mac Studio (marketed as the “Mac Studio”), both manufactured by Apple, Inc. of Cupertino, California. The Mac mini computer is considered a small form factor self-contained desktop computer but does not include a display, keyboard, or mouse. The Mac Studio computer is a larger device as compared to the Mac mini computer, both in terms of the physical device and the provided processing power. Although neither the Mac mini computer nor the Mac Studio computer is typically considered to be a device to be used in a data center, it possesses certain features that make it desirable for deployment in at least some data centers.

For example, the processors and associated internal peripheral circuitry of the Mac mini computer and/or the Mac Studio computer make them highly suitable for hosting development environments for the APPLE® computing infrastructure and environment, which is built around Apple's macOS® operating system for enterprise and personal computing, and the iOS® operating system and/or iPadOS® operating system for mobile devices from Apple, Inc. such as the iPhone® and iPadR. Other conventional types of computer systems, because they lack the unique circuitry and components of the Apple computing environment, are not readily capable of running macOS® or certain iOS® or iPadOS® development platforms, for example. Thus, the Mac mini computer and/or the Mac Studio computer are highly capable of serving data center needs for conventional data center computing requirements, as well as specialized service to the macOS®, iOS®, and iPadOS® development communities.

Unfortunately, the form factors of the Mac mini computer and the Mac Studio computer are not readily suitable for deployment in data centers. For example, the Mac mini computer is manufactured in a small parallelepiped form that contains comparatively large top and bottom panels and comparatively thin lateral sides with rounded edges. Further, the Mac mini computer is manufactured with controls and communication and power ports for the Mac mini computer only on one lateral side. Finally, the Mac mini computer is manufactured with one small fan positioned within its interior that draws air up through the bottom of the Mac mini computer and out the lateral side of the Mac mini computer that contains the controls and ports. The Mac Studio computer is similarly designed, albeit with a larger body as compared to that of the Mac mini computer, and as such, similar difficulties exist when aiming to deploy the Mac Studio in a data center.

As a result of increasing demand by the macOS®, iOS®, and iPadOS® developers' community, there is a need for a data center that can efficiently house computer systems that can provide Apple-compatible hosting environments (e.g., compatibility with macOS®, iOS®, and/or iPadOS®), as well as other cloud-based computing requirements. The present disclosure relates to highly space- and thermal-efficient data center computer rack mounting arrangements that provide for usage of certain computers such as Mac mini computers and/or Mac Studio computers.

Examples of computer center data racks that house Mac Pro and Mac mini computers are shown in U.S. Pat. Nos. 9,756,765; 9,763,354; 10,327,351; 10,602,636; D761,246; and D762,217, which are owned by the same assignee as the present application. The present disclosure provides certain novel and nonobvious improvements and enhancements to the computer center data racks disclosed in these patents.

### BRIEF SUMMARY OF THE DISCLOSURE

As explained more fully herein, aspects of the disclosed technology generally relate to a computer data center rack assembly that allows mounting of numerous Mac mini computers, Mac Studio computers, or similar devices on a single rack (e.g., 96 or more Mac mini computers or similar devices, 48 or more Mac Studio computers or similar devices) on a single rack. The rack can include multiple rails, shelves, or drawers (e.g., 6 rails), and each rail can include multiple rows of computers (e.g., 2 rows of 8 Mac mini computers, 2 rows of 4 Mac Studio computers). The rack can provide accessibility to the Mac mini computers, Mac Studio computers, or similar devices from both sides of the rack and can provide convenient arrangements for power and communications cabling, as well as generally vertical cooling air flow.

Aspects of the disclosed technology generally relate to a rack configured to attach receive and/or arrange (e.g., detachably and/or removably attach) multiple Mac mini computers, Mac Studio computers, or similar devices. The rack can include one or more rails (e.g., drawers or slideable shelves), and each rail can be configured to receive and/or arrange (e.g., detachably and/or removably attach) multiple Mac mini computers or similar devices.

To facilitate easy installation, arrangement and/or serviceability of Mac mini computers, Mac Studio computers, or similar devices, the disclosed technology can include one or more stands configured to at least partially receive one or more Mac mini computers, Mac Studio computers, or similar devices and retain the Mac mini computers, Mac Studio computers, or similar devices in a predetermined configuration and/or arrangement (e.g., rows of upright Mac mini computers and/or Mac Studio computers).

The disclosed technology can include one or more bases, with each base configured to detachably and/or removably attach of a Mac mini computers, Mac Studio computers, or similar devices (e.g., detachably snap onto the outer edge of a Mac mini computer, two pieces thereof configured to detachably attach together to form a structure configured to at least partially envelop a Mac Studio computer). The base can include a separate and distinct secondary computing device (e.g., a single-board computer, such as a Raspberry Pi® or similar device). The secondary computing device can be attached to, or otherwise connected to, the base, and the secondary computing device can be in electrical communication with a physical movement device, such as a servo motor actuator (also referenced herein as a “servo”). The secondary computing device can receive instructions to reset, cycle, or otherwise control operation of the Mac mini computer or Mac Studio computer (or similar device) via a physical button located on the Mac mini computer or Mac Studio computer (or similar device). For example, the secondary computing device can control operation of the servo to physically press a button or switch on the Mac mini computer or Mac Studio computer (or similar device) in response to receiving corresponding instructions. The servo can be attached to, or otherwise connected to (e.g., detachably), the base. The secondary computing device can be in communication with (e.g., receive instructions from) a control device. Alternatively or in addition, the various Mac mini computers or Mac Studios (or similar devices) installed in the rack can be in communication with the control device. The control device can be configured to observe and/or control operation of the rack (or multiple racks) of the Mac mini computers or Mac Studios (or similar devices). The control device can be or include any user computer or other computing device.

The disclosed technology can include a heat channel configured to attach to the base and/or directly to the Mac mini computer, Mac Studio computer, or similar device itself. The heat channel can be configured to help direct heat away from the Mac mini computer, Mac Studio, or other computing device to assist in preventing prevent overheating. As discussed more fully herein, the heat channel can provide an open channel or corridor that can align with that of one or more adjacent (and aligned) other Mac mini computers, Mac Studios, or other computing devices. The heat channel can be positioned in alignment with (e.g., over or atop) the air outlet of the Mac mini computer, Mac Studio, or other computing device, such that the heat channel can direct air flow created by the Mac mini computer, Mac Studio, or other computing device itself.

The disclosed technology can include a handle that can be configured to attach to the heat channel, the base, and/or the Mac mini computer, Mac Studio, or other computing device itself. The handle can be configured to enable easy removal of the Mac mini computer, Mac Studio, or other computing device from a slot of a stand of a rail of the rack (and/or insertion of the Mac mini computer, Mac Studio, or other computing device into a desired slot of a stand of a rail of the rack).

The disclosed technology includes a mounting assembly that can comprise a stand, a base, a motor mount, and a secondary computing device (SCD) mount. The slot can be configured to hold a computer in an upright orientation. The base can comprise a side and a plurality of edge walls. Each edge wall of the plurality of edge walls can be approximately perpendicular to the side, and the side and the plurality of edge walls can define an internal void that is sized and shaped to mirror at least a portion of an exterior shape of the computer. The base can include one or more first motor attachment points and one or more first SCD attachment points. The motor mount can be configured to at least partially receive a motor actuator, and the motor mount can have one or more second motor attachment points, each of the one or more second motor attachment points being configured to detachably attach to a corresponding one of the one or more first motor attachment points. The SCD mount can be configured to attach to a secondary computing device, and the SCD mount can have one or more second SCD attachment points, each of the one or more second SCD attachment points being configured to detachably attach to a corresponding one of the one or more first SCD attachment points.

The base can further comprise one or more upper attachment points. The mounting assembly can further comprise a heat channel rail and a heat channel. The heat channel rail can comprise one or more lower attachment points, each of the one or more lower attachment points being configured to detachably attach to a corresponding one of the one or more upper attachment points; and one or more first heat channel attachment points. The heat channel can comprise a body defining a channel configured to direct air flow and one or more second heat channel attachment points, each of the one or more second heat channel attachment points being configured to detachably attach to a corresponding one of the one or more first heat channel attachment points.

The mounting assembly can further comprise a handle having one or more first handle attachment points. The heat channel rail can further comprise one or more second handle attachment points, each of the one or more second handle attachment points being configured to detachably attach to a corresponding one of the one or more first handle attachment points.

At least some of the one or more second handle attachment points can be located on a top surface of the heat channel rail.

The base can further comprise one or more upper attachment points. The mounting assembly can further comprise a handle having one or more bottom attachment points, each of the one or more bottom attachment points being configured to detachably attach to a corresponding one of the one or more upper attachment points.

The stand can further comprise a plurality of slots. The plurality of slots can include the slot, and each of the plurality of slots can be configured to hold a corresponding computer in the upright orientation.

The slot can be at least partially defined by a side wall having a downwardly curved top edge, and the top edge can mirror a curved protrusion on a face of the computer.

At least one of: the one or more first motor attachment points, the one or more first SCD attachment points, the one or more second motor attachment points, or the one or more second SCD attachment points can comprise a T-shaped protrusion or a T-channel.

The mounting assembly can further comprise the motor actuator and an actuator arm. The motor mount can be configured to position the motor actuator such that the actuator arm can press or release a button on the computer.

The mounting assembly can further comprise the secondary computing device, and the secondary computing device can be in electrical communication with the motor actuator and a control device. The secondary computing device can be configured to receive instructions from the control device and output instructions for the motor actuator to cause the actuator arm to press a power button of the computer.

The side can be a first side, and the plurality of edge walls can be a plurality of first edge walls. The base can further comprise a first base portion comprising the first side, the plurality of first edge walls, and one or more first base attachment mechanisms; and a second base portion comprising a second side, a plurality of second edge walls, and one or more second base attachment mechanisms, each of the one or more second base attachment mechanisms being configured to detachably attach to a corresponding one of the one or more first base attachment mechanisms.

Each of the one or more first base attachment mechanisms can be a snap fit projection, and each of the one or more second base attachment mechanisms can be a snap fit recess.

The stand can be a first stand comprising one or more first attachment apertures located at a position along a perimeter of the first stand. The mounting assembly can further comprise a second stand comprising one or more second attachment apertures located at a position along a perimeter of the second stand; and one or more attachment devices comprising a plurality of attachment protrusions, each attachment protrusion of the plurality of attachment protrusions being configured to detachably attach to at least one of the one or more first attachment apertures and at least one of the one or more second attachment apertures.

The stand can be a first stand, and the mounting assembly can further comprise a second stand and a stand spacer positioned between the first stand and the second stand. The stand spacer can comprise one or more cable channels for organizing cables in a shelf of a computer data center rack.

The disclosed technology includes a mounting assembly that can comprise a stand, a base, a motor mount, and a secondary computing device (SCD) mount. The stand can comprise a slot configured to hold a computer in an upright orientation. The base can comprise a first base portion and a second base portion. The first base portion can comprise a first side; a plurality of first edge walls, each first edge wall of the plurality of first edge walls being approximately perpendicular to the first side, wherein the first side and the plurality of first edge walls define a first internal void sized and shaped to mirror a first portion of an exterior shape of the computer; and one or more first attachment mechanisms. The second base portion can comprise a second side; a plurality of second edge walls, each second edge wall of the plurality of second edge walls being approximately perpendicular to the second side, wherein the second side and the plurality of second edge walls define a second internal void sized and shaped to mirror a second portion of an exterior shape of the computer; and one or more second attachment mechanisms each configured to detachably attach to a corresponding one of the one or more first attachment mechanisms. At least one of the first base portion or the second base portion can further comprise: one or more first motor attachment points; and one or more first secondary computing device (SCD) attachment points. The motor mount can be configured to at least partially receive a motor actuator, and the motor mount can have one or more second motor attachment points, each of the one or more second motor attachment points being configured to detachably attach to a corresponding one of the one or more first motor attachment points. The SCD mount can be configured to attach to a secondary computing device, and the SCD mount can have one or more second SCD attachment points, each of the one or more second SCD attachment points being configured to detachably attach to a corresponding one of the one or more first SCD attachment points.

Each of the one or more first attachment mechanisms can be a snap fit projection, and each of the one or more second attachment mechanisms can be a snap fit recess.

The first base portion can comprise one or more first upper attachment points, and the second base portion comprises one or more second upper attachment points. The mounting assembly can further comprise a first heat channel rail and a second heat channel rail. The first heat channel rail can comprise one or more first lower attachment points, each of the one or more first lower attachment points being configured to detachably attach to a corresponding one of the one or more first upper attachment points. The second heat channel rail can comprise one or more second lower attachment points, each of the one or more second lower attachment points being configured to detachably attach to a corresponding one of the one or more second upper attachment points; and one or more second heat channel attachment points. The mounting assembly can further comprise a heat channel comprising a body defining a channel configured to direct air flow; one or more third heat channel attachment points on a first side of the body, each of the one or more third heat channel attachment points being configured to detachably attach to a corresponding one of the one or more first heat channel attachment points; and one or more fourth heat channel attachment points on a second side of the body, each of the one or more fourth heat channel attachment points being configured to detachably attach to a corresponding one of the one or more second heat channel attachment points.

The first heat channel rail can further comprise one or more first handle attachment points, and the second heat channel rail can further comprise one or more second handle attachment points. The mounting assembly can further comprise a handle comprising: a grip; one or more third handle attachment points, each of the one or more third heat channel attachment being configured to detachably attach to a corresponding one of the one or more first heat channel attachment points; and one or more fourth handle attachment points, each of the one or more fourth heat channel attachment being configured to detachably attach to a corresponding one of the one or more second heat channel attachment points.

The disclosed technology includes computer data center rack comprising a plurality of rack shelves, each rack shelf comprising a plurality of stands. Each stand can comprise a plurality of slots, each configured to hold a corresponding computer in an upright orientation. For each of the computers, the computer data center rack can include a base, a motor, and a secondary computing device (SCD) mount. The base can comprise a side; a plurality of edge walls, each edge wall being approximately perpendicular to the side, wherein the side and the plurality of edge walls define an internal void sized and shaped to mirror at least a portion of an exterior shape of the corresponding computer; one or more first motor attachment points; and one or more first SCD attachment points. The motor mount can be configured to at least partially receive a corresponding motor actuator, and the motor mount can have one or more second motor attachment points, each of the one or more second motor attachment points being configured to detachably attach to a corresponding one of the one or more first motor attachment points. The SCD mount can be configured to attach to a corresponding secondary computing device, and the SCD mount can have one or more second SCD attachment points, each of the one or more second SCD attachment points being configured to detachably attach to a corresponding one of the one or more first SCD attachment points. For each of the computers, the computer data center rack can further include the corresponding motor actuator and an actuator arm, and the motor mount can be configured to position the motor actuator such that the actuator arm is positioned to press a button on the corresponding computer. For each of the computers, the computer data center rack can further include the secondary computing device, and the secondary computing device can be operatively connected to the motor actuator.

The computer data center rack can further comprise a control device operatively connected to each computer of the computer data center rack, and the control device can be located remotely from the computer data center rack. The control device can be configured to output instructions for the secondary computing device to activate the motor actuator to thereby cause the actuator arm to press the power button of one or more selected computers.

These and other aspects, features, and benefits of the disclosed technology will become apparent from the following detailed written description of the preferred embodiments and aspects taken in conjunction with the following drawings, although variations and modifications thereto may be effected without departing from the spirit and scope of the novel concepts of the disclosure.

### BRIEF DESCRIPTION OF THE DRAWINGS

The accompanying drawings illustrate one or more aspects or features of the technology disclosed herein and, together with the written description, serve to explain the principles of the disclosure.

FIG. 1 illustrates an example data center mounting rack with computers mounted therein, in accordance with the disclosed technology.

FIG. 2 illustrates an example shelf of a data center mounting rack with computers mounted therein, in accordance with the disclosed technology.

FIG. 3 illustrates an example shelf of a data center mounting rack with computers mounted therein, in accordance with the disclosed technology.

FIGS. 4A-4C illustrate various views of an example Mac mini computer.

FIGS. 5A and 5B illustrate various views of an example Mac Studio computer.

FIG. 6A illustrates a perspective view of an example stand for receiving multiple Mac computers, FIG. 6B illustrates a top view thereof, and FIG. 6C illustrates a side view thereof, in accordance with the disclosed technology.

FIG. 7A illustrates a perspective view of an example stand for receiving multiple Mac computers, FIG. 7B illustrates a top view thereof, and FIG. 7C illustrates a side view thereof, in accordance with the disclosed technology.

FIGS. 8A-8D illustrate various perspective views of example stand attachment devices, in accordance with the disclosed technology.

FIGS. 9A and 9B illustrate perspective views of an example base, FIG. 9C illustrates a side view thereof, and FIG. 9D illustrates a cross-sectional view thereof, in accordance with the disclosed technology.

FIGS. 9A and 9B illustrate perspective views of an example base, FIG. 9C illustrates a side view thereof, and FIG. 9D illustrates a cross-sectional view thereof, in accordance with the disclosed technology.

FIG. 10A illustrates a perspective view of an example first portion of a base, in accordance with the disclosed technology.

FIG. 10B illustrates a perspective view of an example second portion of a base, in accordance with the disclosed technology.

FIG. 10C illustrates an example assembly of first and second portions of a base, in accordance with the disclosed technology.

FIGS. 11A-11C illustrate perspective views of an example secondary computing device mount, in accordance with the disclosed technology.

FIGS. 12A-12C illustrate an example servo mount, in accordance with the disclosed technology.

FIGS. 13A and 13B illustrate perspective views of an example servo mount, in accordance with the disclosed technology.

FIG. 14 illustrates an example operating environment including various components, in accordance with the disclosed technology.

FIGS. 15A and 15B illustrate perspective views of an example heat channel, in accordance with the disclosed technology.

FIGS. 15C and 15D illustrate perspective views of an example heat channel rail, in accordance with the disclosed technology.

FIG. 16A illustrates a perspective view of an example handle, and FIG. 16B illustrates a cross-sectional view thereof, in accordance with the disclosed technology.

FIG. 17 illustrates an example assembly of various components, in accordance with the disclosed technology.

FIGS. 18A-18C illustrate perspective views of an example heat channel, in accordance with the disclosed technology.

FIG. 19A illustrates a perspective view of an example handle, and FIG. 19B illustrates a cross-sectional view thereof, in accordance with the disclosed technology.

FIG. 20 illustrates an example assembly of various components, in accordance with the disclosed technology.

FIG. 21 illustrates a perspective view of an example stand spacer, in accordance with the disclosed technology.

FIG. 22 illustrates an example heat channel extender, in accordance with the disclosed technology.

### DETAILED DESCRIPTION

For the purpose of promoting an understanding of the principles of the present disclosure, reference will now be made to the drawings and specific language will be used to describe the same. It will, nevertheless, be understood that no limitation of the scope of the disclosure is thereby intended; any alterations and further modifications of the described or illustrated embodiments, and any further applications of the principles of the disclosure as illustrated therein are contemplated as would normally occur to one skilled in the art to which the disclosure relates. All limitations of scope should be determined in accordance with and as expressed in the claims.

Aspects of the present disclosure generally relate to a computer data center rack assembly configured to receive and/or arrange a plurality of Mac mini computers, a plurality of Mac Studio computers, or similar devices. The computer data center rack assembly can include a rack or rack frame infrastructure that can include multiple rails (e.g., rows of drawers and/or slideable shelves), and each rail can be configured to receive a plurality of Mac mini computers, Mac Studio computers, or similar devices. For ease of discussion, the term “Mac computers” will be used herein to generally reference Mac mini computers, Mac Studio computers, or similar devices. As described more fully herein, one or more Mac computers can be detachably attached to a stand, with one or more stands being attached to each rail. The stands can arrange installed Mac computers or other computing devices in a predetermined configuration or arrangement. For example, the various stands can provide an aligned, upright arrangement of Mac computers on each rail of the rack.

A base can be configured to configured to detachably and/or removably attach to a Mac computer or similar device (e.g., detachably snap onto the outer edge of a Mac mini computer), and/or the base can be configured to assemble together such that the Mac computer is at least partially enveloped by the base (e.g., two base pieces detachably attach together to at least partially surround or encompass a Mac Studio computer). A separate and distinct secondary computing device (e.g., a single-board computer, such as a Raspberry Pi® or similar device) can be attached to, or otherwise connected to, the base, and the secondary computing device can be in electrical communication with a physical movement device, such as a servo motor actuator (also referenced herein as a “servo”). The secondary computing device can be configured to receive instructions to reset, cycle, or otherwise control operation of a corresponding Mac computer (or similar device) via a physical button located on the Mac computer (or similar device). For example, the secondary computing device can control operation of the servo to physically press a button or switch on the Mac computer (or similar device) in response to receiving corresponding instructions. The servo can be attached to, or otherwise connected to (e.g., detachably), the base. The secondary computing device can be in communication with (e.g., receive instructions from) a control device. Alternatively or in addition, the various Mac mini computers (or similar devices) installed in the rack can be in communication with the control device. The control device can be configured to observe and/or control operation of the rack (or multiple racks) of the Mac mini computers (or similar devices). The control device can be or include any user computer or other computing device.

As described more fully herein, the secondary computing device and servo can thus remotely perform a task that previously required effort by a data center technician or other person. Such manual efforts are particularly tedious and laborious when many Mac computers or similar devices across the data center require a reset, as the data center technician would be required to physically seek out the particular computing device, manually press the power button, and wait to ensure the computing device successfully reset or restarted before repeating the process for any other problematic computing devices.

A heat channel can be configured to attach to the base and/or to the Mac computer (or other computing device) itself. The heat channel can be configured to help direct heat away from the Mac computer or other computing device (e.g., to prevent overheating). The heat channel can provide an open channel or corridor that can align with that of one or more adjacent (and aligned) other Mac computers or other computing devices. The heat channel can be positioned in alignment with (e.g., over or atop) the air outlet of the Mac computer or other computing device, such that the heat channel can direct air flow created by the Mac computer or other computing device itself.

A handle can be configured to detachably attach to the heat channel, the base, and/or the Mac computer (or other computing device). The handle can be configured to enable easy removal of the Mac computer or other computing device from a slot of a stand of a rail of the rack (and/or insertion of the Mac computer or other computing device into a desired slot of a stand of a rail of the rack). Accordingly, the removable handle can permit easy insertion or removal of a Mac computer without requiring that a permanent handle be attached to each computer or corresponding assembly, which would take up valuable space within the rack.

These and other aspects, features, and benefits of the disclosed technology will become apparent from the following detailed written description and aspects taken in conjunction with the following drawings, although variations and modifications thereto may be effected without departing from the spirit and scope of the novel concepts of the disclosure.

In the following description, numerous specific details are set forth. But it is to be understood that examples of the disclosed technology can be practiced without these specific details. In other instances, well-known methods, structures, and techniques have not been shown in detail in order not to obscure an understanding of this description. References to “one embodiment,” “an embodiment,” “example embodiment,” “some embodiments,” “certain embodiments,” “various embodiments,” “one example,” “an example,” “example examples,” “certain examples,” “various examples,” etc., indicate that the embodiment(s) and/or example(s) of the disclosed technology so described may include a particular feature, structure, or characteristic, but not every embodiment necessarily includes the particular feature, structure, or characteristic. Further, repeated use of the phrases “in one embodiment” or “in one example” does not necessarily refer to the same embodiment or example, although it may.

Throughout the specification and the claims, the following terms take at least the meanings explicitly associated herein, unless the context clearly dictates otherwise. The term “or” is intended to mean an inclusive “or.” Further, the terms “a,” “an,” and “the” are intended to mean one or more unless specified otherwise or clear from the context to be directed to a singular form.

Unless otherwise specified, the use of the ordinal adjectives “first,” “second,” “third,” etc., to describe a common object, merely indicate that different instances of like objects are being referred to, and are not intended to imply that the objects so described should be in a given sequence, either temporally, spatially, in ranking, or in any other manner.

Whether a term is capitalized is not considered definitive or limiting of the meaning of a term. As used in this document, a capitalized term shall have the same meaning as an uncapitalized term, unless the context of the usage specifically indicates that a more restrictive meaning for the capitalized term is intended. However, the capitalization or lack thereof within the remainder of this document is not intended to be necessarily limiting unless the context clearly indicates that such limitation is intended.

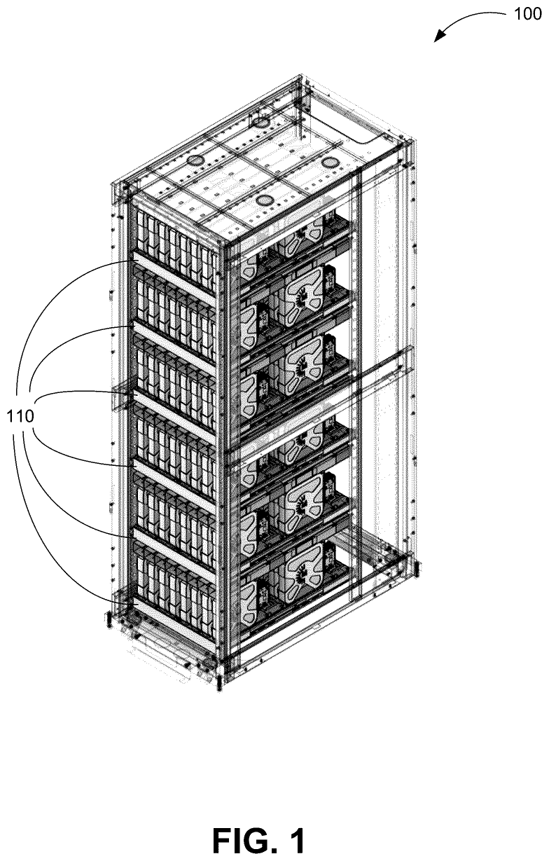

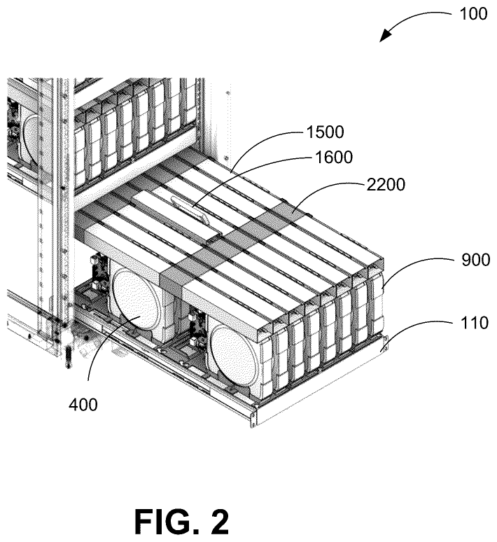

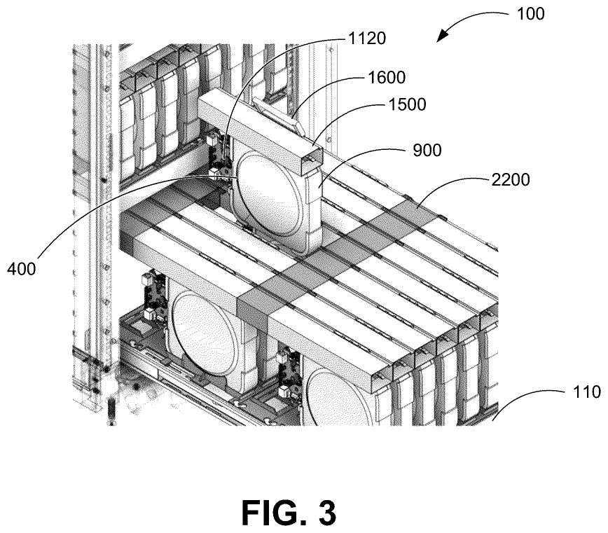

Referring now to FIGS. 1-3, an example data center mounting rack 100 is shown with computers mounted therein. The data center mounting rack 100 (“rack”) can include side panels with cable routing openings, and mounting brackets (e.g., U-shaped mounting brackets). The shelves 110 can be spaced far enough apart to provide for adequate airflow between the Mac computers (e.g., sufficient airflow to keep the Mac computers operating within their optimal temperature range). Alternatively or in addition, the data center mounting rack can include perforated openings (e.g., staggered perforated openings) for air flow positioned between the mounting brackets, which can help facilitate airflow across the various Mac computers. As will be appreciated by one having ordinary skill in the art, if the Mac computers are not cooled adequately, they will overheat and operate inefficiently which, considering the small, single fan, may happen very easily. Alternatively or in addition, the shelves 110 can be spaced far enough apart to provide adequate space for the various cables (e.g., power, network) that are necessary to operate the Mac computers as servers. As will be appreciated, the cables can connect to the rear of the Mac computers and can run in the middle space of the shelves and out the holes in the sides of the data center mounting rack. Furthermore, as described more fully herein, the shelves 110 can include spacers positioned between opposing rows of Mac computers, which can provide an additional avenue for routing cables. To help prevent unnecessary wear on cables, each shelf can include an articulating arm with a channel located therein, which can enable the shelves to extend and retrack from the rack while maintaining the cables in a fixed position between the rear end of the shelf and the rear of the rack.

The rack can hold numerous Mac mini computers (e.g., up to 96) or Mac Studio computers (e.g., up to 48). In either event, the Mac computers can be oriented perpendicularly to the shelves 110 (e.g., such that the computers are in an upright configuration with the computers' intended bottom surface being oriented in a generally vertical position). A given shelf 110 can hold up to 16 Mac mini computers or up to 8 Mac Studio computer, as non-limiting examples. The data center mounting rack 100 can include several shelves 110 (e.g., 6 or more) spaced apart (e.g., equidistantly) within the rack 100. As will be appreciated by one having ordinary skill in the art, the number of shelves 110 (and height of the data center mounting rack 100) can be modified to accommodate the requirements of the data center. For example, the data center mounting rack 100 can comprise 6 or more shelves 110. Alternatively, the data center mounting rack 100 can comprise 5 or fewer shelves 110. It should be appreciated that the specific numbers provided herein (e.g., a rack 100 having 6 rails or shelves 110 each holding 16 Mac mini computers for a total of 96 Mac mini computers or each holding 8 Mac Studio computers for a total of 48 Mac Studio computers) are illustrative and non-limiting. Thus, this disclosure contemplates racks that include more or fewer rails or shelves 110 than the number(s) expressly provided herein, and/or this disclosure contemplates racks 100 and/or rails or shelves 110 that each include more or fewer Mac computers than the number(s) expressly provided herein.

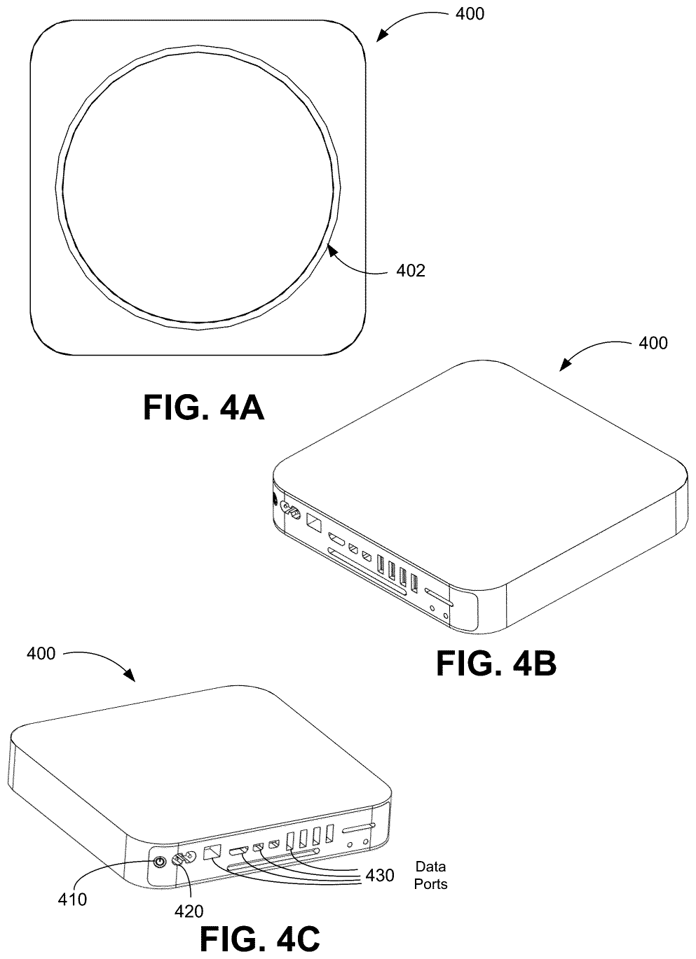

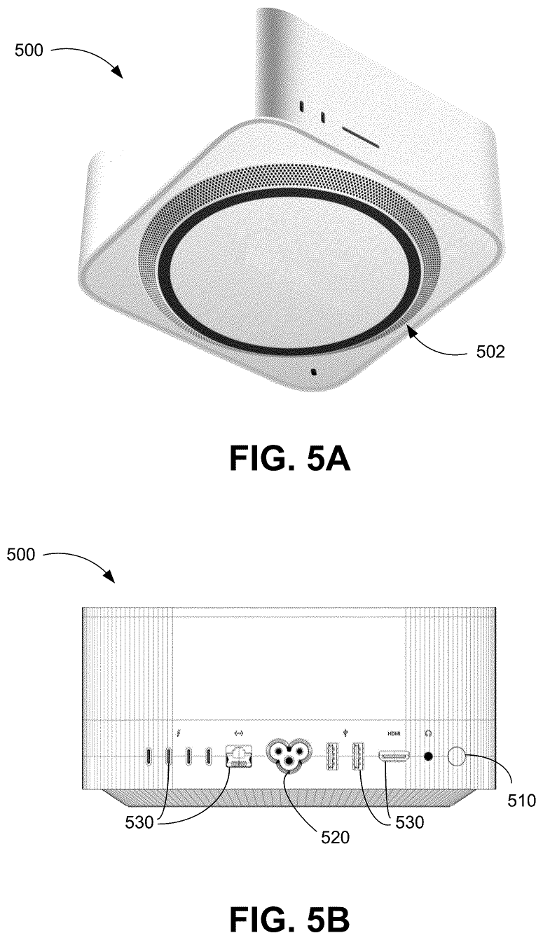

FIGS. 4A-5B illustrate various views of example Mac computers. In particular, FIGS. 4A-4C illustrate an example Mac mini computer 400, and as can be seen, the Mac mini computer 400 can include a pedestal-like, circular base protrusion 402. Further, the Mac mini computer 400 can include a power button 410 (e.g., for turning the Mac mini computer on or off) a power port 420 (e.g., for connecting to a power cord), and various data ports 430 (e.g., for connecting to one or more data cables). The data ports 430, power port 420, and power button 410 can be located on a common side of the Mac mini computer 400. And while the disclosed technology is capable of accommodating these components when they are located on a single side of a computing device (e.g., as on the illustrated Mac mini computer 400), the disclosed technology is not so limited. Indeed, the disclosed technology can accommodate computer housing configurations in which the data ports and/or the power port are located on a side of the computer different from the side on which the power button is located, as a non-limiting example.

FIGS. 5A and 5B illustrate an example Mac Studio computer 500. The Mac Studio computer 500 can include a pedestal-like, circular base protrusion 402. Further, the Mac Studio computer 500 can include a power button 510 (e.g., for turning the Mac Studio computer on or off) a power port 520 (e.g., for connecting to a power cord), and various data ports 530 (e.g., for connecting to one or more data cables). The data ports 530, power port 520, and power button 410 can be located on a common side of the Mac Studio computer 500. And similarly to accommodating the configuration of the Mac mini computer 400, the disclosed technology is capable of accommodating these various components, whether they be located on a single side of a computing device (e.g., as illustrated) or if one, some, or all of the data ports, the power port, or the power button are located on different sides of the computer.

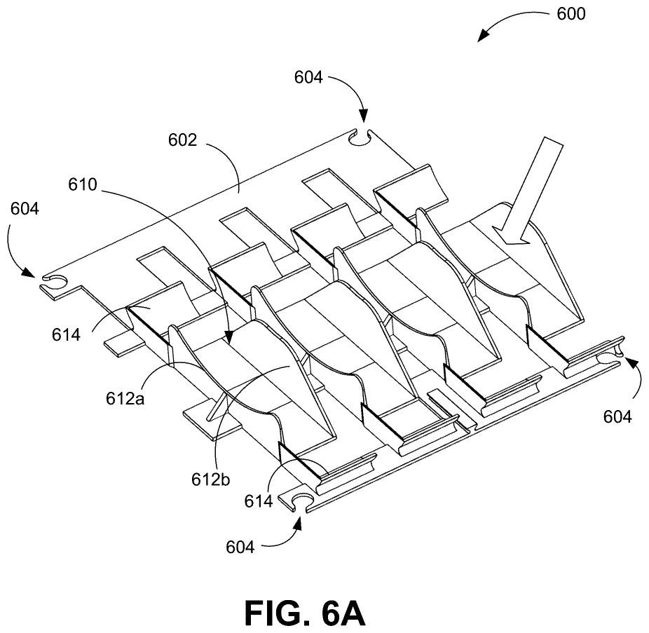

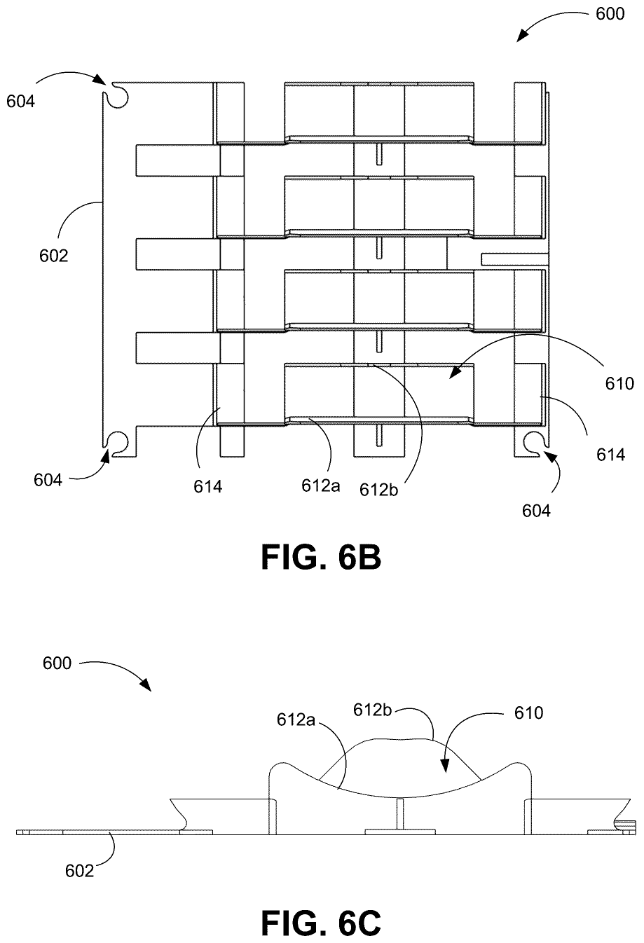

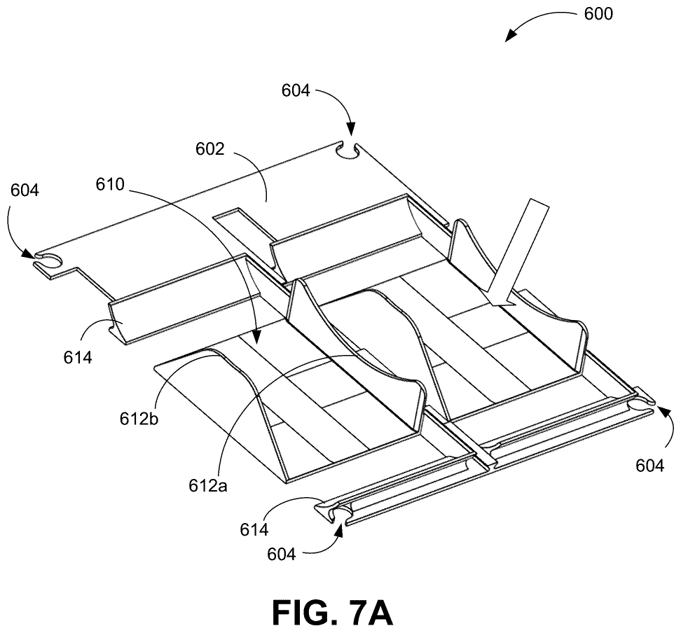

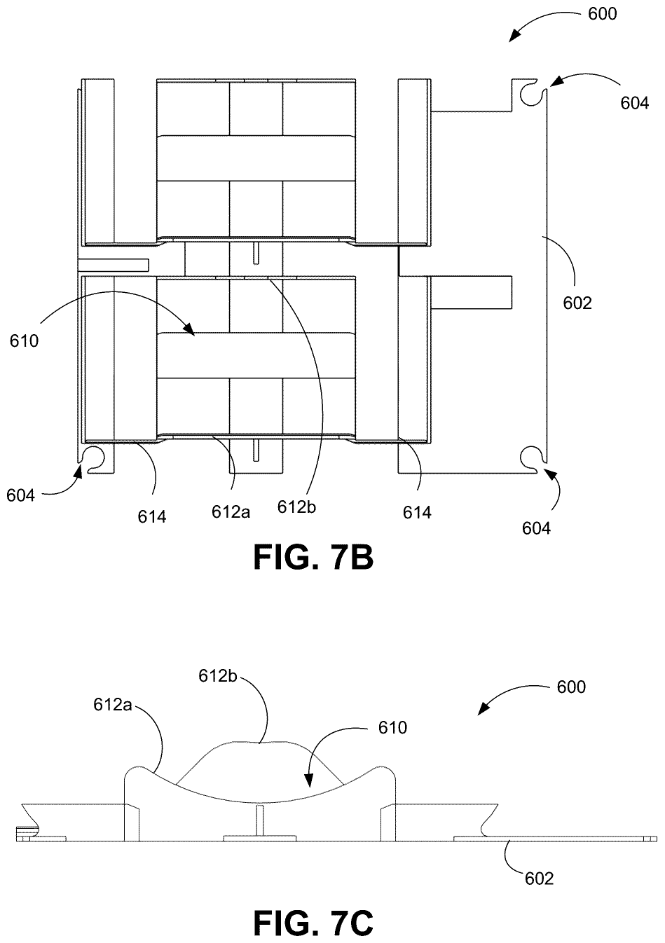

FIGS. 6A-6C and 7A-7C illustrate views of example mounting stands 600 (also referenced as a “stand 600”). The stand 600 can be positioned on or attached to a shelf 110 and can position and orient one or more Mac computers. In particular, FIGS. 6A-6C illustrate an example stand 600 configured to position and orient one or more Mac mini computers 400, and FIGS. 7A-7C illustrate an example stand 600 configured to position and orient one or more Mac Studio computers 500.

The stand 600 can have a bottom 602 and can have multiple slots 610, each configured to receive a corresponding Mac computer. To ensure proper positioning and/or alignment, the slot 610 can include one or more sidewalls 612, and the sidewalls 612 can be shaped and dimensioned to accommodate (e.g., mirror) geometries of the exterior of the Mac computer, thereby ensuring secure positioning of the intended Mac computer. For example, a first sidewall 614a can have a downwardly concave top edge to accommodate the circular base protrusion 402 of the Mac computer's housing. The slot 610 can include a second sidewall 612b opposite first sidewall 612a and can include two curved bookends 614 that are curved to mirror the curved corners of the corresponding Mac computer. Together, the first and second sidewalls 612 and the curved bookends 614 can help maintain the Mac computer in the upright position.

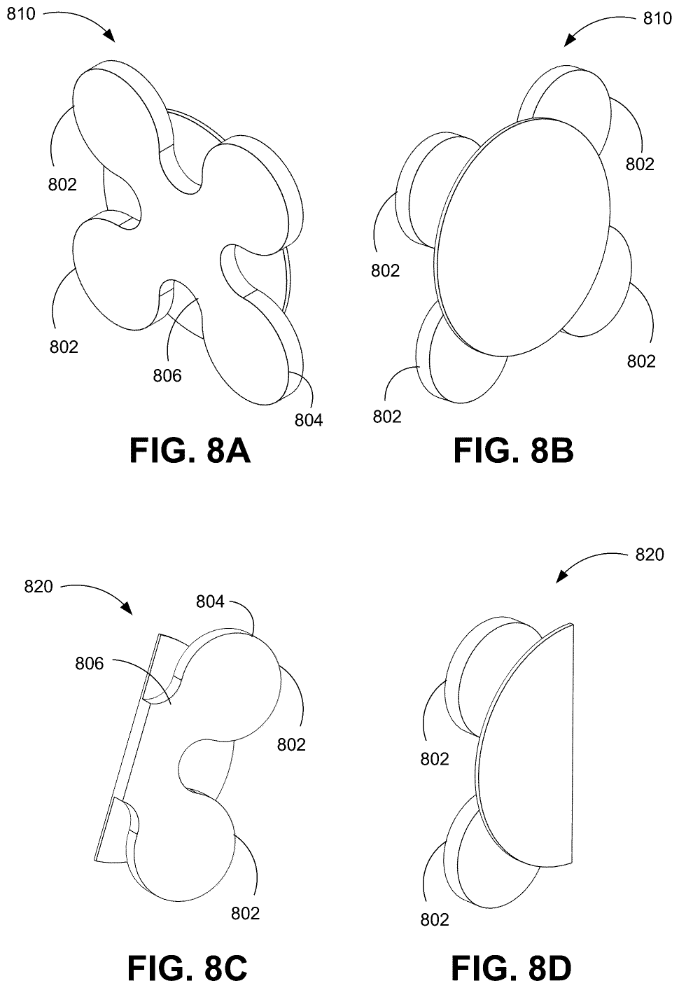

The bottom 602 of the stand can include one or more attachment apertures 604. As illustrated, an attachment aperture 604 is located at each corner of the stand 600. Together with one or more stand attachment devices 810, 820 (examples of which are illustrated in FIGS. 8A-8D), the attachment apertures 604 of adjacent stands 600 (or other components, as described more fully herein) can be connected together, thereby providing a modular functionality of the stands 600. This can increase the stability and security of the stands 600 within the shelf 110, which can thereby increase the stability and security of any Mac computers (or other computing devices) residing therein. Further, the stand 600 (e.g., the bottom 602) can include one or more apertures, rails, slots, recesses, clips, protrusions, or the like to help with cable management, sufficient cooling airflow, etc.

Referring now to FIGS. 8A and 8B, an example first attachment device 810 is illustrated. The first attachment device 810 can include four rounded ends or attachment protrusions 802, each being approximately 90° apart from adjacent attachment protrusions 802. FIGS. 8C and 8D illustrate an example second attachment device 820. The second attachment device 820 can include two rounded ends or attachment protrusions that are approximately 90° apart. The first attachment device 810 can be configured to join together two, three, or four neighboring stands 600, whereas the second attachment device 820 can be configured to join together two neighboring stands 600. Thus, the first attachment device 810 can be particularly well suited for being positioned among multiple stands 600 at an interior position within a shelf 110, and the second attachment device 820 can be particularly well suited for being positioned along an outer edge of stands 600 (e.g., within a shelf 110).

Each attachment protrusion 802 can have a bulbous distal end 804 that is separated from the center of the first attachment device 810 by a comparatively narrow neck 806. The bulbous distal end 804 can have a shape that substantially mirrors at least a portion of the negative space of the attachment aperture 604. The shape of the attachment aperture 604 (or at least a portion thereof) and the corresponding shape of the distal end 804 are not limited to rounded or bulbous shapes and can be any other shape (e.g., square, diamond, triangle, polygonal). In any event, the matching of the comparatively large width of the distal end 804 and the comparatively small width of the neck 806 and a corresponding neck (e.g., the outermost channel portion of the attachment aperture 604) can provide a locking functionality for securing together multiple stands 600. It should be noted that any other attachment device or element (e.g., any detachably attachable attachment device) is contemplated, such that the disclosed technology is not limited to the specific configuration of attachment aperture 604 and attachment devices 810, 820 expressly disclosed herein.

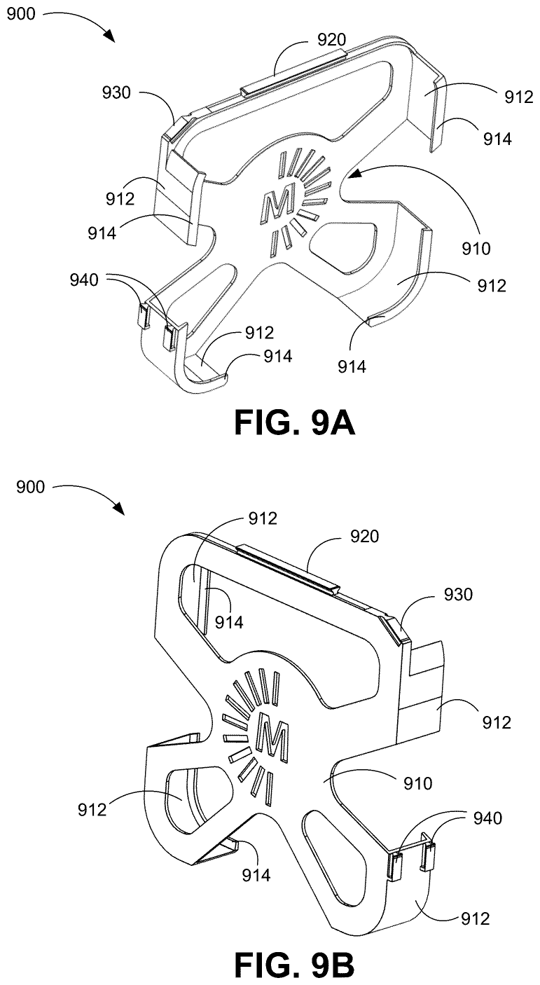

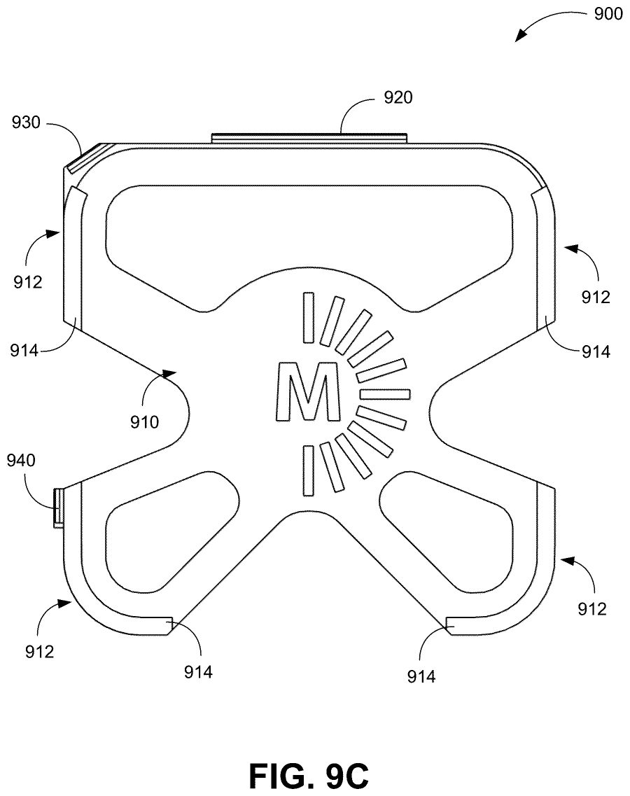

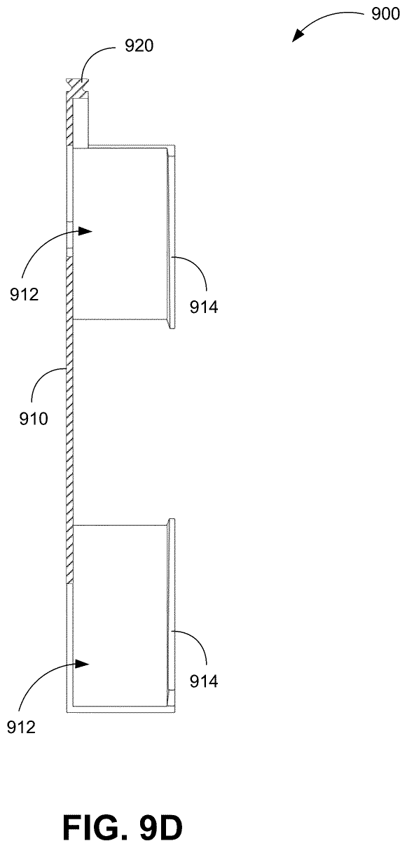

Referring now to FIGS. 9A-9D, disclosed technology can include a base 900 configured to detachably attach to (e.g., snap onto an outer edge of) a Mac computer, such as the Mac mini computer 400. For example, the base 900 can have a side 910 and two or more edge walls 912 extending substantially perpendicularly from the side 910. The edge walls 912 can be configured to extend along and around a corresponding edge of the Mac mini computer 400, and the terminal end of each edge wall 912 can include a lip 914 for detachably securing the base to the Mac mini computer 400.

The base 900 can securely and removably attach to the Mac mini computer 400 and can be configured to receive and/or attach to other components. For example, the base 900 can include attachment points (e.g., protrusions, apertures, rails, slots, clips) for securing (e.g., detachably attaching) the secondary computing device. More specifically, the base 900 can include an upper attachment point 920, one or more servo attachment points 930, and one or more secondary computing device (SCD) attachment points 940. As a non-limiting example, the attachment points 920, 930, 940 can be protrusions extending outwardly from the body of the base (e.g., outwardly from an edge wall 912) and can in the form a T-channel protrusion (and thus configured to slidably insert into a corresponding T-channel).

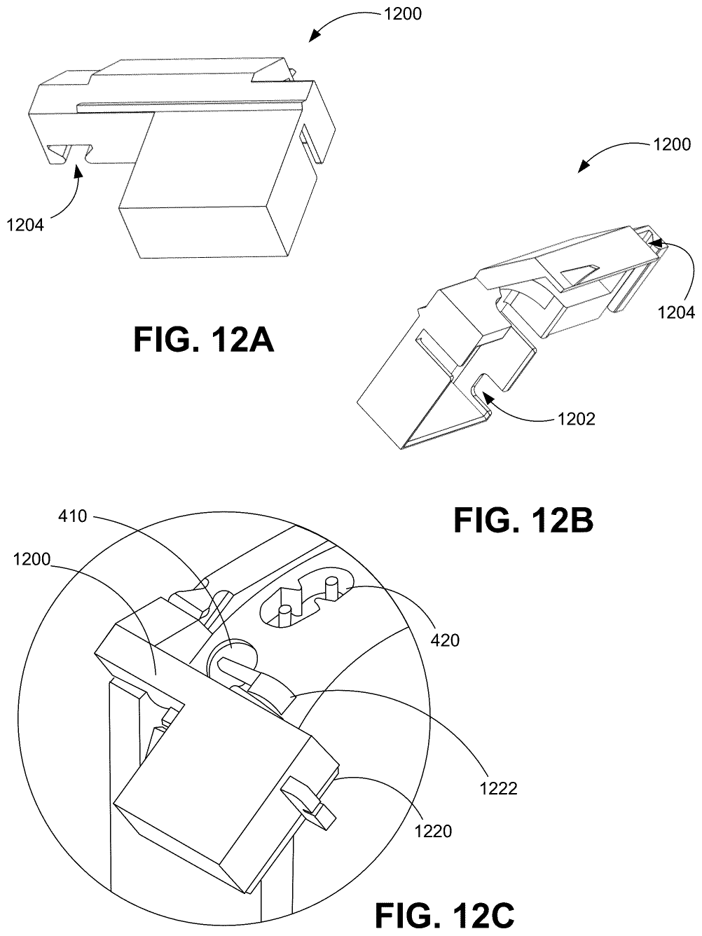

The upper attachment point 920 can be configured to attach to a corresponding components to be positioned above the Mac computer, such as a heat channel, heat channel rail, and/or handle (as discussed more fully herein), or any other component. The servo attachment point 930 can be configured to attach to a servo mount (as discussed more fully herein), which can be configured to maintain a servo motor (or an actuator motor or any other type of mechanism or device configure to press a power button on remote command) in a fixed position relative to the power button 410, 510, of the Mac computer (see, e.g., FIGS. 12A-12C for illustration and additional discussion). The SCD attachment point 940 can be configured to attach to a SCD mount (as discussed more fully herein). The secondary computing device can be operably connected to the servo motor and can be in electrical communication with a remote control device. As such, the control device can be configured to remote control operation of the servo (e.g., to reset, cycle, or otherwise control operation of the Mac computer).

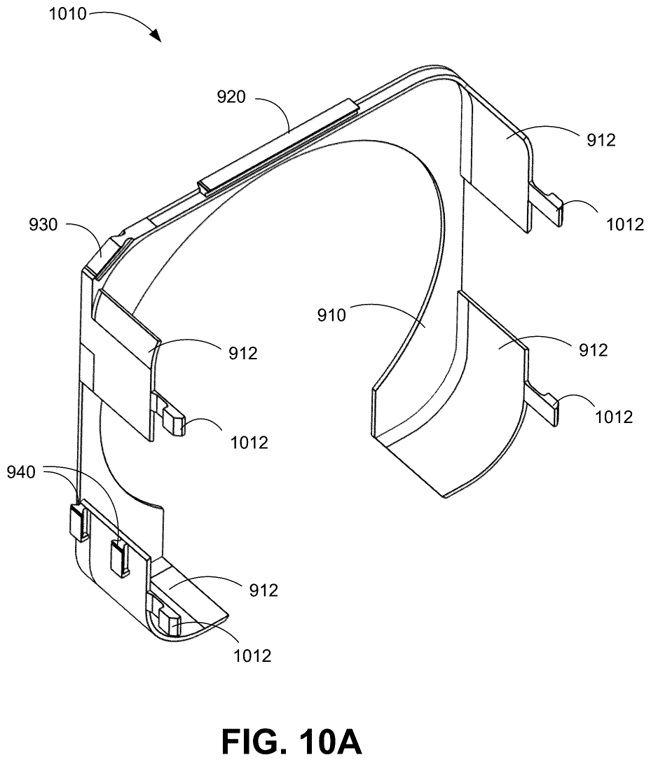

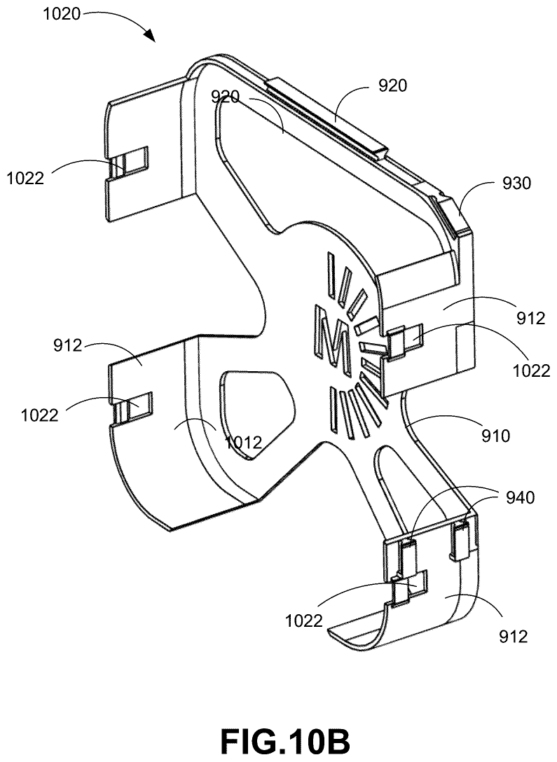

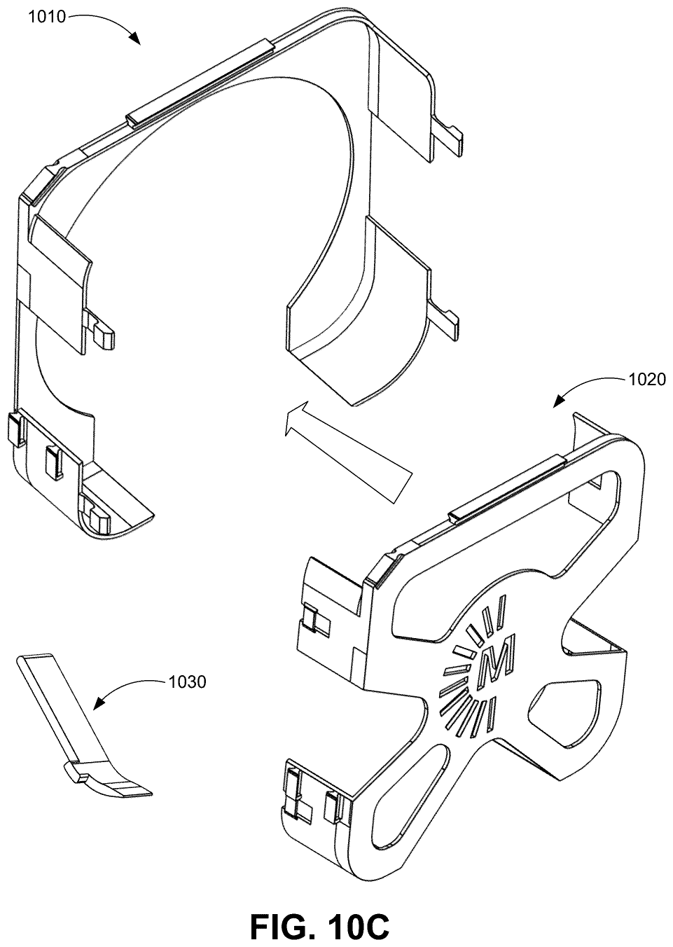

Another example of a base 900 is illustrated in FIGS. 10A-10C. As illustrated, the base 900 can include two portions: a first portion 1010 and a second portion 1020. The first and second portions 1010, 1020 can be configured to detachably connect or attach together, and as such, the first and second portions 1010, 1020 can combine to create a base 900 that at least partially surrounds or envelops the Mac computer. The first portion 1010 can include one or more snap fit projections 1012, and the second portion 1020 can include corresponding snap fit recesses 1022. The snap fit projections 1012 can include a lip that seats into the corresponding snap fit recess 1022 to connect the first and second portions 1010, 1020.

The disclosed technology includes a separation tool 1030, which can be or include a pry bar configured to pry apart the first portion 1010 from the second portion 1020 to thereby increase the case by which the two portions 1010, 1020 can be separated.

Alternatively or in addition, the base 900 can include two upper attachment points 920 (e.g., one on the first portion 1010 and one on the second portion 1020), which can help better distribute weight for larger computing devices, such as the Mac Studio 500.

As illustrated, the base 900 (regardless of whether there is one or more portions of the base 900) can include various protrusions, apertures, rails, slots, and/or clips for interfacing with and/or securing (e.g., detachably attaching to) one or more other components of the computer data center rack assembly, such as the secondary computing device, the servo, the heat channel, and/or the handle. Alternatively or in addition, additional components, such as a temperature sensor and/or a display (e.g., LED or OLED display) can be secured or otherwise attached to base 900 (e.g., via one of the disclosed attachment points, via an additional attachment point,).

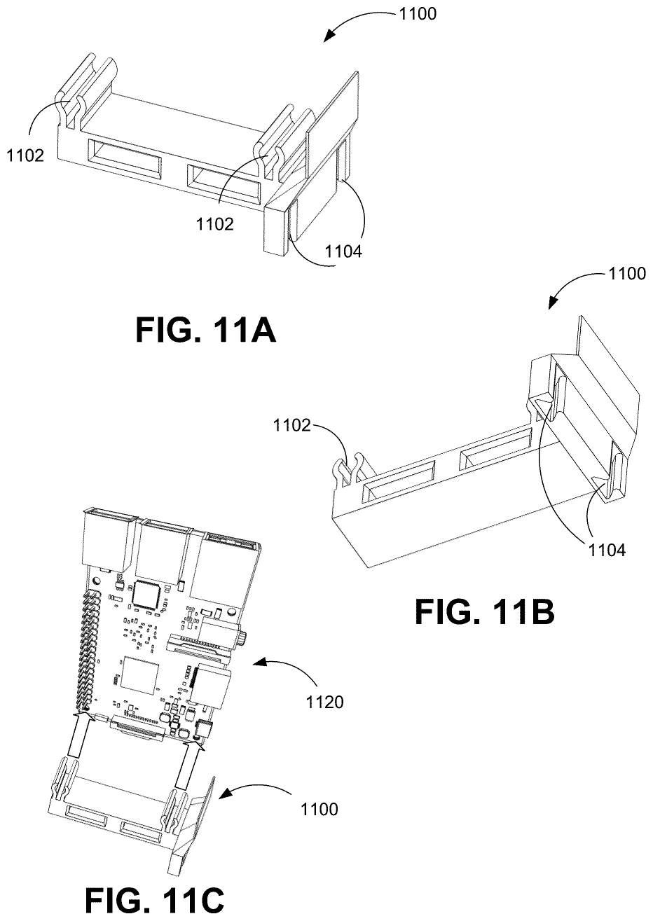

Referring now to FIGS. 11A-11C, an example secondary computing device (SCD) mount 1100 is illustrated. The SCD mount 1100 can include one or more apertures or slots 1102 for mounting the secondary computing device 1120 to the SCD mount 1100. For example, the slot 1102 can be configured to at least partially receive a screw or bolt configured to attach to the printed circuit board (PCB) or other component of the secondary computing device 1120. The SCD mount 1100 can include one or more SCD attachment channels 1104 (e.g., T-channels) that are configured to slidably receive at least a portion of the protrusion of a corresponding SCD attachment point 940 of the base 900. As such, the SCD mount 1100 can detachably attach a secondary computing device 1120 to the base 900 to securely locate the secondary computing device 1120 within the shelf 110 and in close proximity to the Mac computer and servo with which the secondary computing device 1120 is associated.

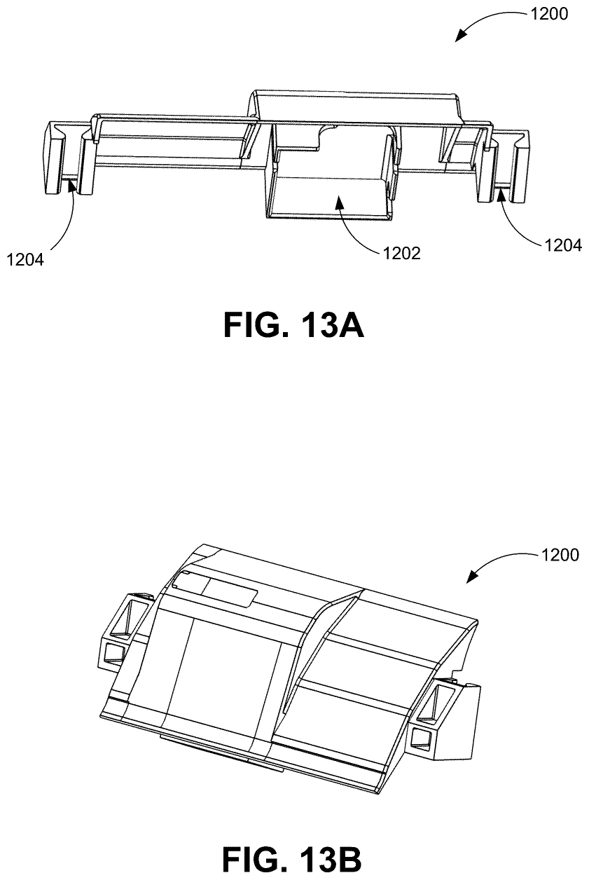

Example servo mounts are illustrated in FIGS. 12A-13B. A first example servo mount 1200 is shown in FIGS. 12A-12C. The servo mount 1200 can include a body defining a servo cavity 1202 that is sized and dimensioned to at least partially receive a servo motor (or actuator or other mechanical device). The servo mount 1200 can include one or more servo attachment channels 1204 (e.g., T-channels) that are configured to slidably receive at least a portion of the protrusion of a corresponding servo attachment point 930 of the base 900. A second example servo mount 1200 is shown in FIGS. 13A and 13B. The second example servo mount 1200 includes two servo attachment channels 1204, whereas the first example servo mount 1200 includes only one servo attachment channel 1204, as illustrated. Further, the second example servo mount 900 has a different body configuration and different positioning of the servo cavity 1202 to accurately position the servo to interact with the power button 410, 510 of a corresponding type of computing device. For example, as illustrated, the first example servo mount 1200 would be particularly useful with a Mac mini, and the second example servo mount 1200 would be particularly useful with a Mac Studio.

Referring in particular to FIG. 12C, the servo mount 1200 can detachably attach a servo 1220 to the base 900 to securely locate the servo 1220 in the correct position to contact the power button 410, 510 of a corresponding Mac computer or other computing device. For example, the servo 1220 can include a servo arm 1222 attached to the servo 1220 such that the servo 1220 can cause the servo arm 1222 to press and/or release the power button 410, 510 of a corresponding Mac computer (or other computing device).

The servo 1220 can be in electrical communication with a corresponding secondary computing device 1120. The secondary computing device 1120 can be or include a single-board computer. For example, the secondary computing device 1120 can be or include a Raspberry Pi® or similar device. Regardless of the specific computing device used, the secondary computing device 1120 can be attached to the Mac computer via the base 900 or a different mounting bracket (e.g., a mounting bracket dedicated for the secondary computing device). Alternatively, the secondary computing device 1120 can be mounted to the rack or can be remotely located (i.e., remote from the Mac computer and/or rack 100). Regardless, the secondary computing device 1120 can be in electrical communication with the servo 1220, whether via wired or wireless connection.

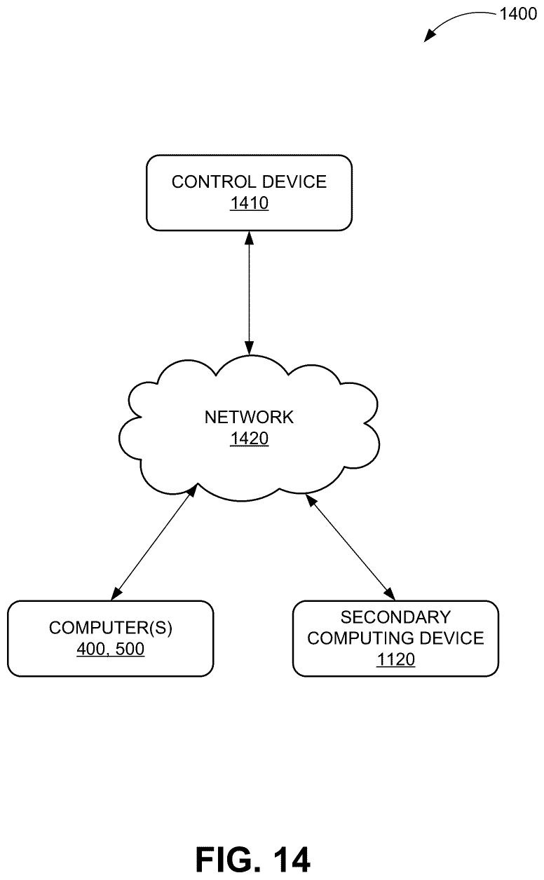

As illustrated in FIG. 14, an operating environment 1400 can include the secondary computing device 1120, the computer 400, 500, and a control device 1410. The various components of the operating environment can be configured to communicate directly or via a network 1420. The control device 1410 can be or include any user computer or other computing device. The control device 1410 can be operated by a technician of the data center including the rack 100. Alternatively or in addition, the control device 1410 can be operated by a customer of the data center. Alternatively or in addition, the control device 1410 can be in electrical communication with multiple computers 400, 500 and/or secondary computing devices 1120, such as all such devices in a given rack 100 or all such devices across multiple racks in a computer data center.

The secondary computing device 1120 can receive instructions from the control device 1410 to reset, cycle, or otherwise control operation of the Mac computer (or similar device) via a physical button located on the Mac computer (or similar device). For example, the secondary computing device 1120 can control operation of the servo 1220 to physically press a button or other switch on the Mac computer (or similar device) in response to receiving instructions from the control device 1410. Stated otherwise, the secondary computing device 1120 can output instructions for the servo 1220 to operate to press the power button 410, 510 (or another button or switch) of the Mac computer (e.g., in response to receiving corresponding instructions from the control device 1410).

As will be appreciated, the disclosed technology (e.g., the servo 1220 and secondary computing device 1120) can enable a technician and/or customer to operate a specific Mac computer without requiring assistance from an onsite human. Further, the technician and/or customer can operate the Mac computer remotely from anywhere in the world (provided there is a communication connection between the control device operated by the technician and/or customer and the secondary computing device). Moreover, by enabling customers to communicate with the secondary computing device 1120 and/or operate the servo 1220, the customer are thus enabled to work with one or more specific Mac computers on a programmatic basis.

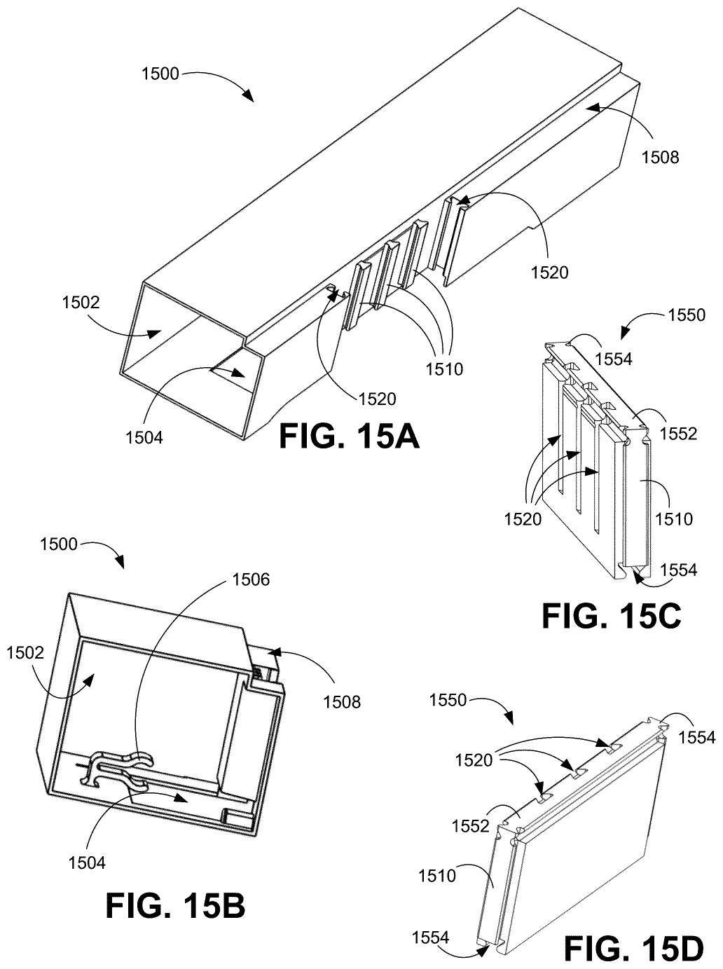

FIGS. 15A and 15B show various views of an example heat channel 1500, which is attachable to a base 900. As illustrated, the heat channel 1500 can provide a longitudinal channel 1502 (or tunnel or corridor) through which air can flow. The bottom of the heat channel can include one or more apertures 1504, which can be aligned with the air outlet(s) of the Mac mini computer. As illustrated, the heat channel 1500 can be placed atop the side of the Mac computer (e.g., a Mac mini computer) that includes the power port 420, the power button 410, and/or one or more data ports 430. As will be understood by those having skill in the art, the air outlet(s) of the Mac mini computer can be located on or near the same side of the Mac computer as the power port 420, the power button 410, and/or one or more data ports 430. As such, the air outlet(s) of the Mac computer can be in fluid communication with the longitudinal channel 1502 of the heat channel 1500 (e.g., via the apertures 1504), such that the heat channel 1502 can be configured to effect the movement and/or dispersement of heat away from the Mac computer, thereby helping to facilitate a cooling effect for the Mac computer. The heat channel 1500 can thus be configured to help effect cooling of the Mac computer using only the air movement provided by a fan integrated in the Mac computer itself. That is to say, the overall computer data center rack 100 can omit any dedicated fans or other air movement devices (e.g., any air movement devices other than those included in the Mac computers).

The heat channel 1500 can be configured to accommodate access for the servo to the power button of the Mac mini computer. For example, the heat channel can provide an opening (e.g., include an aperture) for the servo to be positioned near (e.g., adjacent to) the power button, such that the servo can selectively physically contact the power button of the Mac mini computer.

The heat channel is shown as having a substantially square or rectangular cross-sectional shape, but the disclosed technology is not so limited. For example, the heat channel can have a rounded (e.g., substantially circular) cross-sectional shape or any other cross-sectional shape. Alternatively or in addition, the heat channel can include one or more retaining clips 1506, which can help guide or restrain cables or the like and/or maintain attachment between the heat channel 1500 and the base 900 and/or between the heat channel 1500 and the Mac computer.

Referring now to FIGS. 15A-15D, the heat channel 1500 can be configured to attach to the base 900 via a heat channel rail 1550. The heat channel 1500 can include one or more rail attachment points 1510, 1520. One or more of the rail attachment points 1510 can be or comprise a protrusion (e.g., a T-shaped protrusion), and/or one or more of the rail attachment points 1520 can be or include a channel (e.g., a T-channel). The various rail attachment points 1510, 1520 can be generally parallel. Similarly, the heat channel rail 1550 can include one or more rail attachment points 1510, 1520, which can be or include a protrusion (e.g., a T-shaped protrusion) and/or a channel (e.g., a T-channel). The rail attachment points 1510, 1520 on the heat channel 1500 can mirror corresponding rail attachment points 1510, 1520 on the heat channel rail 1550. For example, protruding heat channel attachment points 1510 on the heat channel 1500 can correspond to recessed or channeled heat channel attachment points 1520 on the heat channel rail 1550, and protruding heat channel attachment points 1510 on the heat channel rail 1550 can correspond to recessed or channeled heat channel attachment points 1520 on the heat channel 1500.

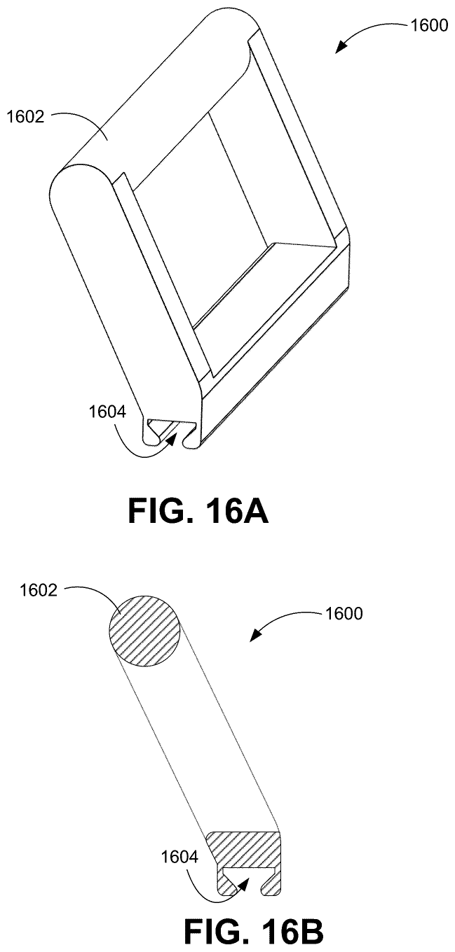

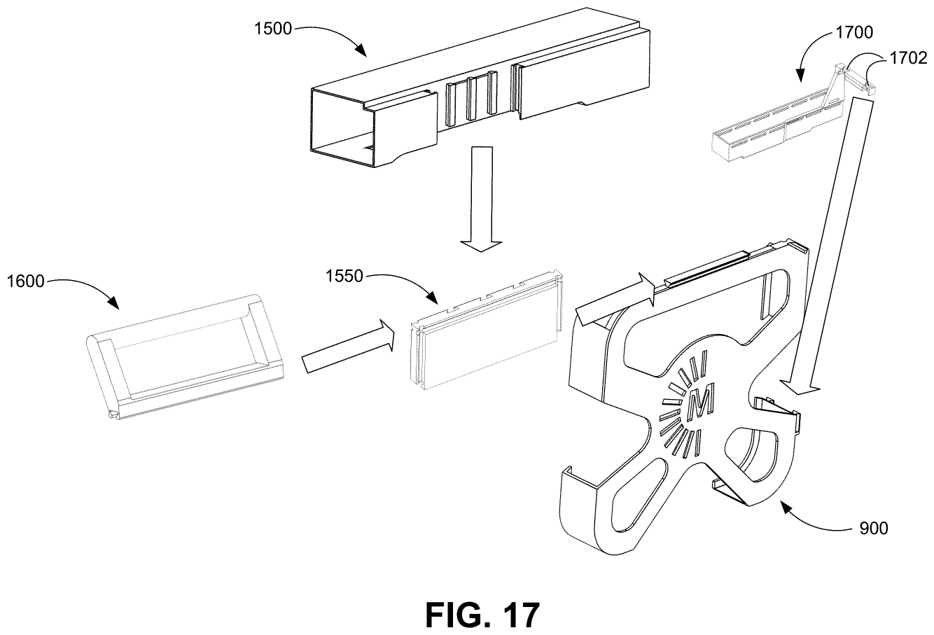

Further, the heat channel rail 1550 can include a base attachment point 1552 on the bottom of the heat channel rail 1550 and a handle attachment point 1554 on the top of the heat channel rail 1550. The base attachment point 1552 can be configured to slidably engage the upper attachment point 920 of the base 900, as a non-limiting example. The heat channel rail 1550 can be sized such that the handle attachment point 1554 is proud of an adjacent edge of the heat channel 1500 when the heat channel 1500 and the heat channel rail 1550 are attached to the base 900. For example, the heat channel 1500 can include a step 1508 that is lower than the top of the heat channel. As will be appreciated, the height difference between the adjacent top of the heat channel 1500 (e.g., at the step 1508) and the handle attachment point 1554 of the heat channel rail 1550 will enable the handle to slidably engage the handle attachment point 1554 to help facilitate easy movement of the Mac computer, such as easy installation and/or removal of the Mac computer relative to the rack 100. As shown in FIGS. 16A and 16B, the handle 1600 can include a grip 1602 and a handle attachment point 1604 slidably attaching to the heat channel rail 1550 or some other component, as desired.

As illustrated in FIG. 16, various components described herein can be slidably attached to one another to form a rigid structure capable of being removed from a rack 100 via the handle 1600. For example, the heat channel rail 1550 can be attached to the base 900 (e.g., via the upper attachment point 920 and the base attachment point 1552), the heat channel 1500 can be attached to the heat channel rail 1550 (e.g., via the rail attachment points 1510, 1520), and the handle 1600 can be attached to the heat channel rail 1550 (e.g., via the handle attachment point 1554 and the handle attachment point 1604). It should be noted that assembly of the various components is not limited to the order of operations explicitly described herein.

Additional components can be attached to the base, if desired. For example, an accessory holder 1700 can be attached to the base 900 via accessor attachment points 1702, which can be configured to slidably engage the SCD attachment points 940 (e.g., in addition to the SCD mount 1100) or any other attachment points on the base 900 or any other component.

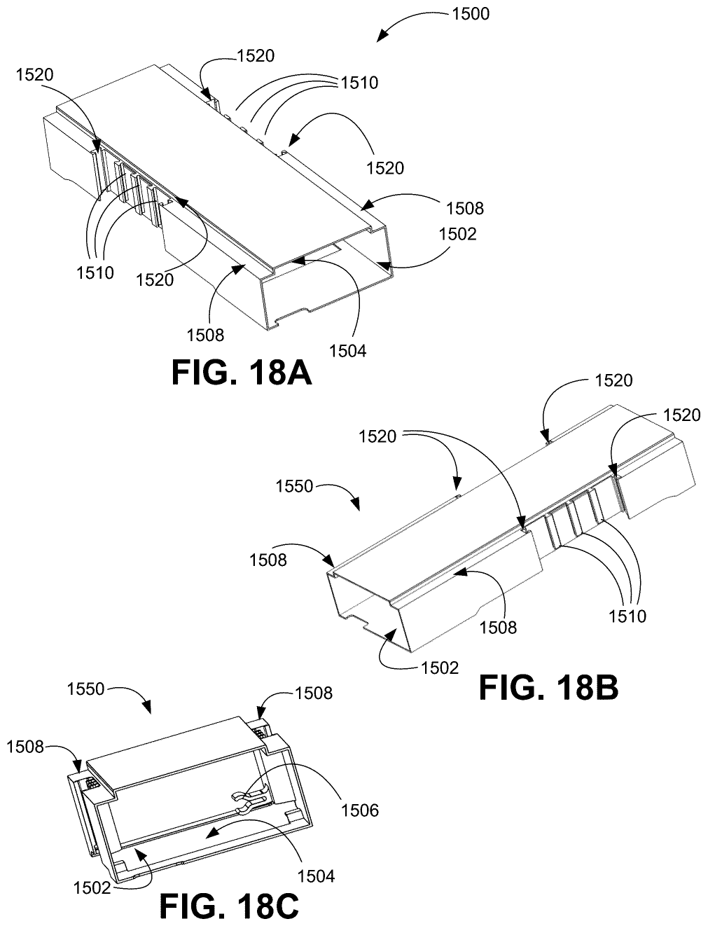

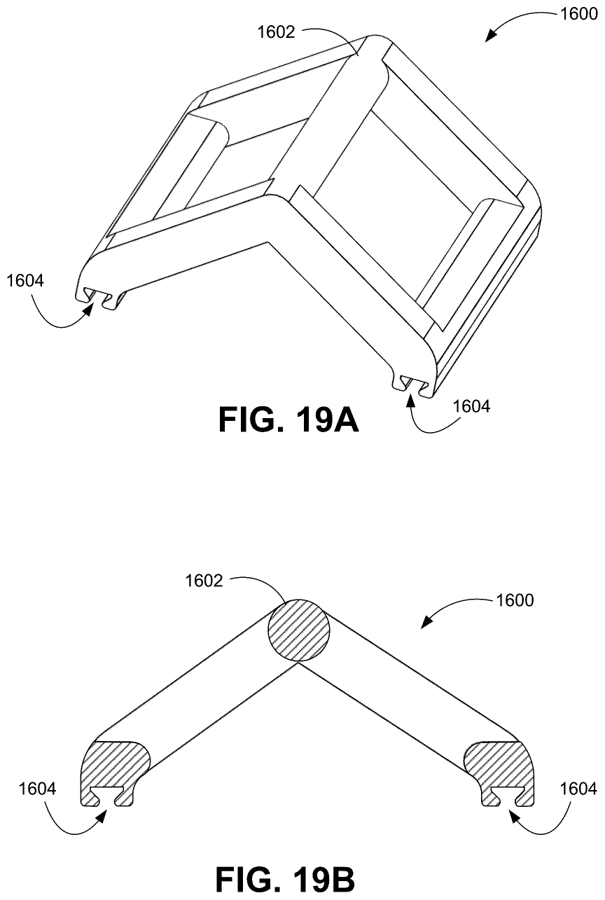

Referring now to FIGS. 18A-18C, a second example heat channel 1500 is shown. The second example heat channel 1500 is similar to the first example heat channel discussed with respect to FIGS. 15A and 15B. The second example heat channel 1500 can include steps 1508 on opposite, longitudinal sides of the heat channel 1500 and can include two sets of rail attachment points 1510, 1520 on those opposite, longitudinal sides, each being configured to engage a corresponding heat channel rail 1550. Given that two heat channel rails 1550 are utilized in this configuration, a second example handle 1600 can include two a handle attachment point 1604 on opposite sides of the grip 1602, and the handle attachment points 1604 can be configured to slidably engage a corresponding one of the heat channel rails 1550 (or some other component, as desired). The second example handle 1600 is illustrated in FIGS. 19A and 19B.

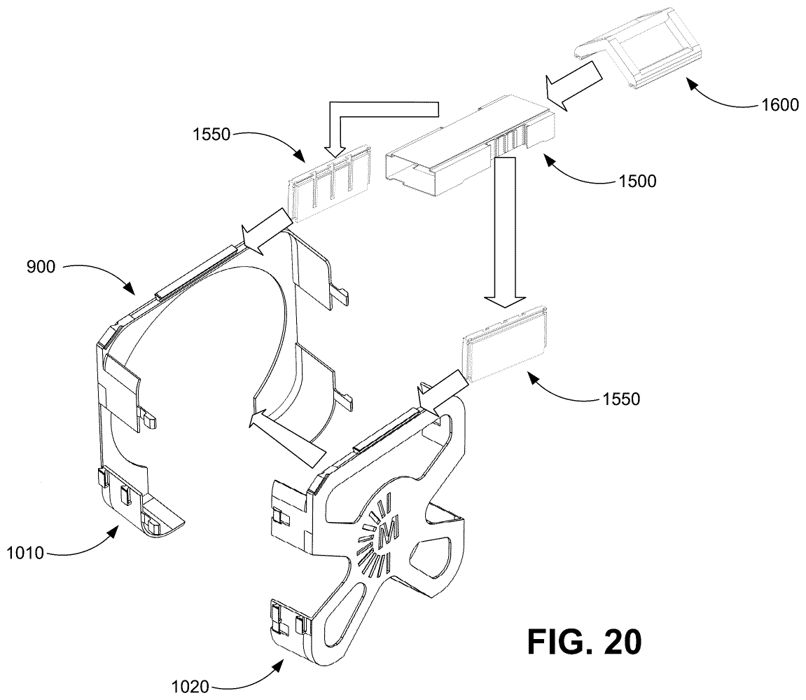

While the first example heat channel 1500 is particularly well suited to attach to the one-piece base 900, the second example heat channel 1500 is particularly well suited to attach to the two-piece base 900. To illustrate, FIG. 20 shows an example assembly process of various components described herein to form a rigid structure capable of being removed from a rack 100 via the handle 1600. For example, the first portion 1010 of the base 900 can be attached to the second portion 1020 of the base 900, two opposing heat channel rail 1550 can be attached to the base 900 (e.g., one being attached to the upper attachment point 920 of the first portion 1010 via its base attachment point 1552 and the other being attached to the upper attachment point 920 of the second portion 1020 via its base attachment point 1552), the heat channel 1500 can be attached to the heat channel rails 1550 (e.g., via the various rail attachment points 1510, 1520), and the handle 1600 can be attached to the heat channel rails 1550 (e.g., via the handle attachment points 1554 and the corresponding handle attachment points 1604). It should be noted that assembly of the various components is not limited to the order of operations explicitly described herein.

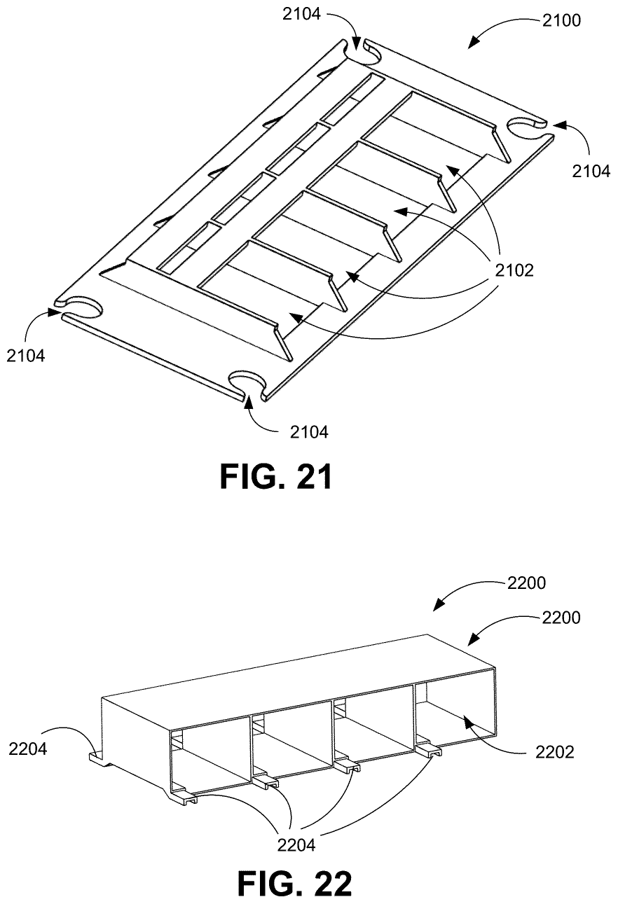

Referring now to FIG. 21, it can be advantageous to include one or more spacers between rows of Mac computers. For example, a stand spacer 2100 can be positioned directly between two stands 600 to separate the Mac computers, which can be advantageous from a cooling perspective, a weight management perspective (e.g., for a given shelf 110), and/or from a cable management perspective (e.g., by providing additional room to route cables from the Mac computers to the rear of the shelf 110). The stand spacer 2100 can include one or more channels 2102 that can direct cables across the shelf 110, and the stand spacer 2100 can be configured to attach to other stand spacers 2100 and/or to stands 600 via the same or similar components that connect the stands 600 together. For example, the stand spacer 2100 can include an attachment aperture 2104, which can be the same as, or similar to, the attachment aperture 604 of the stands 600. For example, the attachment aperture 2104 can be configured to mate with the attachment protrusion 802 of an attachment device 810, 820, as described more fully herein.

And as shown in FIG. 22, it can be advantageous to include one or more heat channel extenders 2200, which can direct air flow via an extender channel 2202 from a first heat channel 1500 to a neighboring but spaced apart second heat channel 1500. As illustrated, the heat channel extender 2200 is configured to fluidly connect two neighboring rows of up to four heat channels 1500, but the disclosed technology is not so limited and can include fewer or more extender channels 2202. The heat channel extender 2200 can be configured to attach to, or otherwise connect to, the heat channels 1500 via one or more tabs 2204.

The various components described herein can be made—in whole or in part—using any useful material, such as one or more metals and/or one or more plastics. For example, the rack can comprise metal, whereas the stand, the base, the heat channel, and/or the handle can comprise and/or consist of one or more plastics. Various components (e.g., the stand 600, the base 900, the attachment devices 810, 820, the SCD mount 1100, the servo mount 1200, the heat channel 1500, the heat channel rail 1550, the handle 1600, the stand spacer 2100, and/or the heat channel extender 2200) can be manufactured via additive manufacturing techniques, via molding techniques (e.g., injection molding), or any other manufacturing method.

As explained herein, the disclosed technology provides several benefits over existing data center systems. For example, the disclosed technology can provide worldwide access to operational capabilities and/or efficiencies (e.g., without an onsite operator at the data center) and can extend physical features or functions of a Mac computer (or similar device) to remote technicians and/or customers. Moreover, the base 900 and the servo mount 1200 can efficiently position the servo 1220 relative the Mac computer, which can provide an increased server density in the data center.

The foregoing description of the exemplary embodiments has been presented only for the purposes of illustration and description and is not intended to be exhaustive or to limit the inventions to the precise forms disclosed. Many modifications and variations are possible in light of the above teaching.

The examples provided herein were chosen and described in order to explain the principles of the disclosed technology and their practical application so as to enable others skilled in the art to utilize the disclosed technology and with various modifications as are suited to the particular use contemplated. Alternative embodiments of the disclosed technology will become apparent to those skilled in the art without departing from the spirit and scope of the disclosed technology.

Accordingly, the scope of the present inventions is defined by the appended claims rather than the foregoing description and the exemplary embodiments described therein.

What is claimed is:

1. A mounting assembly comprising:
a stand comprising a slot configured to hold a computer in an upright orientation;
a base comprising:
a side;
a plurality of edge walls, each edge wall of the plurality of edge walls being approximately perpendicular to the side, wherein the side and the plurality of edge walls define an internal void sized and shaped to mirror at least a portion of an exterior shape of the computer;
one or more first motor attachment points; and
one or more first secondary computing device (SCD) attachment points;
a motor mount configured to at least partially receive a motor actuator, the motor mount having one or more second motor attachment points, each of the one or more second motor attachment points being configured to detachably attach to a corresponding one of the one or more first motor attachment points; and
a SCD mount configured to attach to a secondary computing device, the SCD mount having one or more second SCD attachment points, each of the one or more second SCD attachment points being configured to detachably attach to a corresponding one of the one or more first SCD attachment points.

2. The mounting assembly of claim 1, wherein:
the base further comprises one or more upper attachment points; and
the mounting assembly further comprises:
a heat channel rail comprising:
one or more lower attachment points, each of the one or more lower attachment points being configured to detachably attach to a corresponding one of the one or more upper attachment points; and
one or more first heat channel attachment points; and
a heat channel comprising:
a body defining a channel configured to direct air flow; and
one or more second heat channel attachment points, each of the one or more second heat channel attachment points being configured to detachably attach to a corresponding one of the one or more first heat channel attachment points.

3. The mounting assembly of claim 2 further comprising:
a handle having one or more first handle attachment points,
wherein the heat channel rail further comprises one or more second handle attachment points, each of the one or more second handle attachment points being configured to detachably attach to a corresponding one of the one or more first handle attachment points.

4. The mounting assembly of claim 3, wherein at least some of the one or more second handle attachment points are located on a top surface of the heat channel rail.

5. The mounting assembly of claim 1, wherein:
the base further comprises one or more upper attachment points; and
the mounting assembly further comprises a handle having one or more bottom attachment points, each of the one or more bottom attachment points being configured to detachably attach to a corresponding one of the one or more upper attachment points.

6. The mounting assembly of claim 1, wherein the stand further comprises a plurality of slots including the slot, each of the plurality of slots being configured to hold a corresponding computer in the upright orientation.

7. The mounting assembly of claim 1, wherein the slot is at least partially defined by a side wall having a downwardly curved top edge, the top edge mirroring a curved protrusion on a face of the computer.

8. The mounting assembly of claim 1, wherein at least one of the one or more first motor attachment points, the one or more first SCD attachment points, the one or more second motor attachment points, or the one or more second SCD attachment points comprises a T-shaped protrusion or a T-channel.

9. The mounting assembly of claim 1 further comprising the motor actuator and an actuator arm, wherein the motor mount is configured to position the motor actuator such that the actuator arm can press or release a button on the computer.

10. The mounting assembly of claim 9 further comprising the secondary computing device, wherein the secondary computing device is in electrical communication with the motor actuator and a control device, wherein the secondary computing device is configured to:
receive instructions from the control device; and
output instructions for the motor actuator to cause the actuator arm to press a power button of the computer.

11. The mounting assembly of claim 1, wherein:
the side is a first side;
the plurality of edge walls is a plurality of first edge walls; and
the base further comprises:
a first base portion comprising the first side, the plurality of first edge walls, and one or more first base attachment mechanisms; and
a second base portion comprising a second side, a plurality of second edge walls, and one or more second base attachment mechanisms, each of the one or more second base attachment mechanisms being configured to detachably attach to a corresponding one of the one or more first base attachment mechanisms.

12. The mounting assembly of claim 11, wherein each of the one or more first base attachment mechanisms is a snap fit projection and each of the one or more second base attachment mechanisms is a snap fit recess.

13. The mounting assembly of claim 1, wherein:
the stand is a first stand comprising one or more first attachment apertures located at a position along a perimeter of the first stand; and
the mounting assembly further comprises:
a second stand comprising one or more second attachment apertures located at a position along a perimeter of the second stand; and
one or more attachment devices comprising a plurality of attachment protrusions, each attachment protrusion of the plurality of attachment protrusions being configured to detachably attach to at least one of the one or more first attachment apertures and at least one of the one or more second attachment apertures.

14. The mounting assembly of claim 1, wherein:
the stand is a first stand; and
the mounting assembly further comprises:
a second stand; and
a stand spacer positioned between the first stand and the second stand, the stand spacer comprising one or more cable channels for organizing cables in a shelf of a computer data center rack.

15. A mounting assembly comprising:
a stand comprising a slot configured to hold a computer in an upright orientation;
a base comprising:
a first base portion comprising:
a first side;
a plurality of first edge walls, each first edge wall of the plurality of first edge walls being approximately perpendicular to the first side, wherein the first side and the plurality of first edge walls define a first internal void sized and shaped to mirror a first portion of an exterior shape of the computer; and
one or more first attachment mechanisms; and
a second base portion comprising:
a second side;
a plurality of second edge walls, each second edge wall of the plurality of second edge walls being approximately perpendicular to the second side, wherein the second side and the plurality of second edge walls define a second internal void sized and shaped to mirror a second portion of an exterior shape of the computer; and
one or more second attachment mechanisms each configured to detachably attach to a corresponding one of the one or more first attachment mechanisms,
wherein at least one of the first base portion or the second base portion further comprises:
one or more first motor attachment points; and
one or more first secondary computing device (SCD) attachment points;
a motor mount configured to at least partially receive a motor actuator, the motor mount having one or more second motor attachment points, each of the one or more second motor attachment points being configured to detachably attach to a corresponding one of the one or more first motor attachment points; and
a SCD mount configured to attach to a secondary computing device, the SCD mount having one or more second SCD attachment points, each of the one or more second SCD attachment points being configured to detachably attach to a corresponding one of the one or more first SCD attachment points.

16. The mounting assembly of claim 15, wherein each of the one or more first attachment mechanisms is a snap fit projection and each of the one or more second attachment mechanisms is a snap fit recess.

17. The mounting assembly of claim 15, wherein:
the first base portion comprises one or more first upper attachment points;
the second base portion comprises one or more second upper attachment points; and
the mounting assembly further comprises:
a first heat channel rail comprising:
one or more first lower attachment points, each of the one or more first lower attachment points being configured to detachably attach to a corresponding one of the one or more first upper attachment points; and
a second heat channel rail comprising:
one or more second lower attachment points, each of the one or more second lower attachment points being configured to detachably attach to a corresponding one of the one or more second upper attachment points; and
one or more second heat channel attachment points; and
a heat channel comprising:
a body defining a channel configured to direct air flow;
one or more third heat channel attachment points on a first side of the body, each of the one or more third heat channel attachment points being configured to detachably attach to a corresponding one of the one or more first heat channel attachment points; and
one or more fourth heat channel attachment points on a second side of the body, each of the one or more fourth heat channel attachment points being configured to detachably attach to a corresponding one of the one or more second heat channel attachment points.

18. The mounting assembly of claim 17, wherein:
the first heat channel rail further comprises one or more first handle attachment points;
the second heat channel rail further comprises one or more second handle attachment points; and
the mounting assembly further comprises a handle comprising:
a grip;
one or more third handle attachment points, each of the one or more third heat channel attachment being configured to detachably attach to a corresponding one of the one or more first heat channel attachment points; and
one or more fourth handle attachment points, each of the one or more fourth heat channel attachment being configured to detachably attach to a corresponding one of the one or more second heat channel attachment points.

19. A computer data center rack comprising:
a plurality of rack shelves, each rack shelf comprising:
a plurality of stands, each stand comprising a plurality of slots each configured to hold a corresponding computer in an upright orientation; and
for each computer:
a base comprising:
a side;
a plurality of edge walls, each edge wall being approximately perpendicular to the side, wherein the side and the plurality of edge walls define an internal void sized and shaped to mirror at least a portion of an exterior shape of the corresponding computer;
one or more first motor attachment points; and
one or more first secondary computing device (SCD) attachment points;
a motor mount configured to at least partially receive a corresponding motor actuator, the motor mount having one or more second motor attachment points, each of the one or more second motor attachment points being configured to detachably attach to a corresponding one of the one or more first motor attachment points;
a SCD mount configured to attach to a corresponding secondary computing device, the SCD mount having one or more second SCD attachment points, each of the one or more second SCD attachment points being configured to detachably attach to a corresponding one of the one or more first SCD attachment points;
the corresponding motor actuator and an actuator arm, wherein the motor mount is configured to position the motor actuator such that the actuator arm is positioned to press a button on the corresponding computer; and
the secondary computing device, wherein the secondary computing device is operatively connected to the motor actuator.

20. The computer data center rack of claim 19 further comprising a control device operatively connected to each computer of the computer data center rack, wherein the control device is located remotely from the computer data center rack and is configured to:
output instructions for the secondary computing device to activate the motor actuator to thereby cause the actuator arm to press the power button of one or more selected computers.
